(19) United States
(12) Patent Application Publication
(10) Pub. No.: US 2026/0344156 A1
(43) Pub. Date: Oct. 29, 2026

(54) Display Device

(71) Applicant: LG Display Co., Ltd., Seoul (KR)

(72) Inventors: HeumeIl Baek, Seoul (KR); Jaeyong Choi, Paju-si (KR)

(21) Appl. No.: 19/632,009

(22) Filed: Mar. 27, 2026

(30) Foreign Application Priority Data
Apr. 29, 2025 (KR) 10-2025-0056208

(51) Int. Cl. H10H 29/80; H10H 29/49

(52) U.S. Cl. CPC H10H 29/8325; H10H 29/49

(57) ABSTRACT

A display device includes a substrate, a driving transistor and a power line disposed to be spaced apart from each other on the substrate, a plurality of light emitting elements including a first light emitting element and a second light emitting element connected in series with the first light emitting element, and a shared electrode disposed on the substrate. Each of the first light emitting element and the second light emitting element includes a first electrode and a second electrode, the second electrode of the first light emitting element is electrically connected to the driving transistor, the first electrode of the second light emitting element is electrically connected to the power line, and the shared electrode is electrically connected to the first electrode of the second light emitting element and the second electrode of the first light emitting element. Accordingly, power consumption of the display device may be reduced.

### CROSS-REFERENCE TO RELATED APPLICATION

This application claims the priority to Republic of Korea Patent Application No. 10-2025-0056208, filed on Apr. 29, 2025, which is incorporated herein by reference in its entirety.

### BACKGROUND

### Field

The present disclosure relates to a display device, and more particularly, for example, without limitation, to a display device with reduced power consumption.

### Description of Related Art

Display devices used for a monitor of a computer, a TV, or a mobile phone include an organic light emitting display (OLED) that emits light by itself, and a liquid crystal display (LCD) that requires a separate light source.

Display devices have been applied in a variety of applications, including computer monitors and TVs as well as personal portable devices, and research is being conducted on display devices that have a large display area and have a reduced volume and weight.

In addition, recently, a display device including a light emitting diode (LED) has attracted attention as a next-generation display device. Since the LED is made of an inorganic material rather than an organic material, reliability is excellent, and a lifespan thereof is longer than that of a liquid crystal display device or an organic light emitting display device. Further, the LED has a fast lighting speed, excellent luminous efficiency, and a strong impact resistance so that a stability is excellent and an image having a high luminance can be displayed.

### SUMMARY

An object to be achieved by the present disclosure is to provide a display device in which a plurality of light emitting elements are connected in series to be driven with low power in terms of reducing power consumption.

An object to be achieved by the present disclosure is to provide a display device in which a plurality of light emitting elements is disposed in one sub pixel to implement high resolution.

An object to be achieved by the present disclosure is to provide a display device in which even though any one of a plurality of light emitting elements is defective, the remaining light emitting elements may be normally driven.

An object to be achieved by the present disclosure is to provide a display device capable of repairing a defective light emitting element.

Objects of the present disclosure are not limited to the above-mentioned objects, and other objects, which are not mentioned above, can be clearly understood by those skilled in the art from the following descriptions.

According to one or more embodiments of the present disclosure, a display device includes a substrate on which a plurality of sub pixels are defined, a driving transistor and a power line disposed to be spaced apart from each other on the substrate, a plurality of light emitting elements including a first light emitting element disposed in at least some of the plurality of sub pixels and a second light emitting element connected in series with the first light emitting element, and a shared electrode disposed on the substrate and electrically connecting the first light emitting element and the second light emitting element in at least some of the plurality of sub pixels, the first light emitting element and the second light emitting element each include a first electrode and a second electrode, the second electrode of the first light emitting element is electrically connected to the driving transistor, the first electrode of the second light emitting element is electrically connected to the power line, and the shared electrode is electrically connected to the first electrode of the second light emitting element and the second electrode of the first light emitting element. Accordingly, power consumption may be reduced.

According to one or more embodiments of the present disclosure, a display device includes a substrate on which a plurality of sub pixels are defined, a power line for supplying power to the plurality of sub pixels, the power line disposed on the substrate, and a planarization layer disposed further from the substrate than the power line in a cross-sectional view of the display device. A first sub pixel of the plurality of sub pixels includes a driving transistor between the planarization layer and the substrate in the cross-sectional view of the display device, a shared electrode disposed on the planarization layer, a first light emitting element disposed on the planarization layer, the first light emitting element including a first electrode connected to the shared electrode and a second electrode connected to the driving transistor, and a second light emitting element disposed on the planarization layer, the second light emitting element including a first electrode connected to the power line and a second electrode connected to the shared electrode.

Other detailed matters of the embodiments are included in the detailed description and the drawings.

According to one or more embodiments of the present disclosure, a high-resolution display device may be implemented by disposing a plurality of light emitting elements connected in series to a sub pixel.

According to one or more embodiments of the present disclosure, the display device may be driven with low power in terms of reducing power consumption.

According to one or more embodiments of the present disclosure, it is possible to easily repair a defective light emitting element.

According to one or more embodiments of the present disclosure, even if a defect occurs in one light emitting element among a plurality of light emitting elements connected in series, the remaining light emitting elements are normally driven to minimize or reduce a dark spot defect of a sub pixel.

The effects according to the present disclosure are not limited to the contents exemplified above, and more various effects are included in the present disclosure.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are exemplary and explanatory and are intended to provide further explanation of the inventive concepts as claimed.

### BRIEF DESCRIPTION OF THE DRAWINGS

The above and other embodiments, features and other advantages of the present disclosure will be more clearly understood from the following detailed description taken in conjunction with the accompanying drawings, in which:

FIG. 1 is a schematic block diagram of a display device according to one or more embodiments of the present disclosure.

FIG. 2A is a partial cross-sectional view of a display device according to one or more embodiments of the present disclosure.

FIG. 2B is a perspective view of a tiling display device according to one or more embodiments of the present disclosure.

FIG. 3 is a circuit diagram of a sub pixel of a display device according to one or more embodiments of the present disclosure.

FIG. 4 is a plan view of a sub pixel of a display device according to one or more embodiments of the present disclosure.

FIG. 5A is a cross-sectional view taken along the line Va-Va’ of FIG. 3 according to one or more embodiments of the present disclosure.

FIG. 5B is a cross-sectional view taken along the line Vb-Vb’ of FIG. 3 according to one or more embodiments of the present disclosure.

FIG. 6 is a plan view of a sub pixel of a display device according to one or more embodiments of the present disclosure.

FIG. 7 is a cross-sectional view taken along the line VII-VII' of FIG. 6 according to one or more embodiments of the present disclosure.

FIG. 8 is a plan view of a sub pixel of a display device according to one or more embodiments of the present disclosure.

FIG. 9 is a cross-sectional view taken along the line IX-IX' of FIG. 8 according to one or more embodiments of the present disclosure.

FIGS. 10A to 10C are plan views of a pixel of a display device according to one or more embodiments of the present disclosure.

FIG. 11 is a plan view of a sub pixel of a display device according to one or more other embodiments of the present disclosure.

FIG. 12 is a cross-sectional view taken along the line XII-XII' of FIG. 11 according to one or more other embodiments of the present disclosure.

FIG. 13 is a plan view of a sub pixel of a display device according to one or more other embodiments of the present disclosure.

FIG. 14 is a cross-sectional view taken along the line XIV-XIV’ of FIG. 13 according to one or more other embodiments of the present disclosure.

FIG. 15 is a plan view of a sub pixel of a display device according to one or more other embodiments of the present disclosure.

FIG. 16 is a cross-sectional view taken along the line XVI-XVI' of FIG. 14 according to one or more other embodiments of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted or may be briefly discussed. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Any implementation described herein as an “example” is not necessarily to be construed as preferred or advantageous over other implementations.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

In describing a temporal relationship, when the temporal order is described as, for example, “after,” “subsequent,” “next,” and “before” a case that is not continuous may be included unless a more limiting term, such as “just,” “immediate(ly),” or “direct(ly)” is used.

Also, when an element or layer is “connected,” “coupled,” or “adhered” to another element or layer denotes that the element or layer can not only be directly connected or adhered to another element or layer, but also be indirectly connected or adhered to another element or layer with one or more intervening elements or layers “disposed,” or “interposed” between the elements or layers, unless otherwise specified. It should be understood to mean that elements may be so disposed to directly contact each other, or may be so disposed without directly contacting each other.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Like reference numerals generally denote like elements throughout the disclosure.

A size and a thickness of each component illustrated in the drawing are illustrated for convenience of description, and the present disclosure is not limited to the size and the thickness of the component illustrated.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these embodiments may be provided so that this disclosure may be sufficiently thorough and complete to assist those skilled in the art to fully understand the scope of the present disclosure. Furthermore, the present disclosure is only defined by scopes of claims.

The features of various embodiments of the present disclosure can be partially or entirely adhered to or combined with each other and can be interlocked and operated in technically various ways, and the embodiments can be carried out independently of or in association with each other.

Hereinafter, the present disclosure will be described in detail with reference to the drawings.

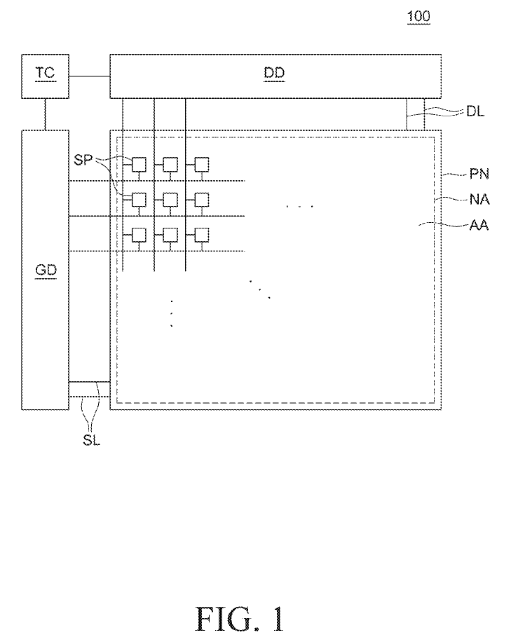

FIG. 1 is a schematic block diagram of a display device according to one or more embodiments of the present disclosure. In FIG. 1, for the convenience of description, among various components of the display device 100, only a display panel PN, a gate driver GD, a data driver DD, and a timing controller TC are illustrated.

Referring to FIG. 1, a display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals provided from the timing controller TC. FIG. 1 illustrates that one gate driver GD is disposed to be spaced apart from one side of the display panel PN. However, the number and arrangement of the gate drivers GD are not limited thereto.

The data driver DD may convert image data input from the timing controller TC into a data voltage using a reference gamma voltage in response to a plurality of data control signals provided from the timing controller TC and supply the converted data voltage to the plurality of data lines DL.

The timing controller TC aligns image data input from the outside and supplies the image data to the data driver DD. The timing controller TC may generate a gate control signal and a data control signal using a synchronization signal input from the outside. Further, the timing controller TC supplies the generated gate control signal and data control signal to the gate driver GD and the data driver DD, respectively, to control the gate driver GD and the data driver DD.

The display panel PN is configured to display images to a user and includes a plurality of sub pixels SP. In the display panel PN, the plurality of scan lines SL and the plurality of data lines DL intersect each other, and each of the plurality of sub pixels SP is connected to the scan line SL and the data line DL. In addition, although not illustrated in the drawings, each of the plurality of sub pixels SP may be connected to a high potential power line, a low potential power line, a reference line, and the like.

In the display panel PN, a display area AA and a non-display area NA enclosing the display area AA may be defined. The display area AA is an area in which images are displayed in the display device 100. In the display area AA, a plurality of sub pixels SP constituting a plurality of pixels PX and a circuit for driving the plurality of sub pixels SP may be disposed. The plurality of sub pixels SP is a minimum unit constituting the display area AA, and n sub pixels SP may form one pixel PX. In each of the plurality of sub pixels SP, a light emitting element, a thin film transistor for driving the light emitting element, and the like may be disposed. The plurality of light emitting elements may be differently defined depending on the type of the display panel PN. For example, when the display panel PN is an inorganic light emitting display panel, the light emitting element may be a light emitting element (LED) or a micro light emitting element (micro-LED).

In the display area AA, a plurality of signal lines for transmitting various signals to the plurality of sub pixels SP is disposed. For example, the plurality of signal lines may include a plurality of data lines DL which supplies a data voltage to each of the plurality of sub pixels SP, a plurality of scan lines SL which supplies a gate voltage to each of the plurality of sub pixels SP, and the like. The plurality of scan lines SL may extend in one direction in the display area AA and be connected to the plurality of sub pixels SP, and the plurality of data lines DL may extend in a direction different from the one direction in the display area AA and be connected to the plurality of sub pixels SP. In addition, in the display area AA, a low potential power line, a high potential power line, and the like may be further disposed, but are not limited thereto.

The non-display area NA is an area where an image is not displayed and may be defined as an area extending from the display area AA. In the non-display area NA, a link line and a pad electrode for transmitting a signal to the sub pixel SP of the display area AA, or a driving integrated circuit (IC), such as a gate driver IC or a data driver IC, may be disposed. The non-display area NA may be located on a rear surface of the display panel PN, that is, a surface on which the sub pixels SP are not disposed or may be omitted, and is not limited as illustrated in the drawing.

Meanwhile, a driver such as a gate driver GD, a data driver DD, and a timing controller TC may be connected to the display panel PN in various ways. For example, the gate driver GD may be mounted in the non-display area NA in a gate-in-panel (GIP) manner or mounted between the plurality of sub pixels SP in the display area AA in a gate-in-display area (GIA) manner. For example, the data driver DD and the timing controller TC are formed in separate flexible film and printed circuit board and may be electrically connected to the display panel PN by bonding the flexible film and the printed circuit board to the pad electrode formed in the non-display area NA of the display panel PN. If the gate driver GD is mounted in the GIP manner and the data driver DD and the timing controller TC transmit signals to the display panel PN through the pad electrode of the non-display area NA, it is necessary to secure the area of the non-display area NA for disposing the gate driver GD and the pad electrode, and the bezel may increase.

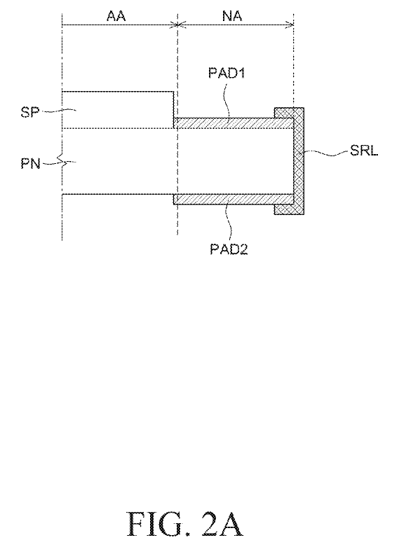

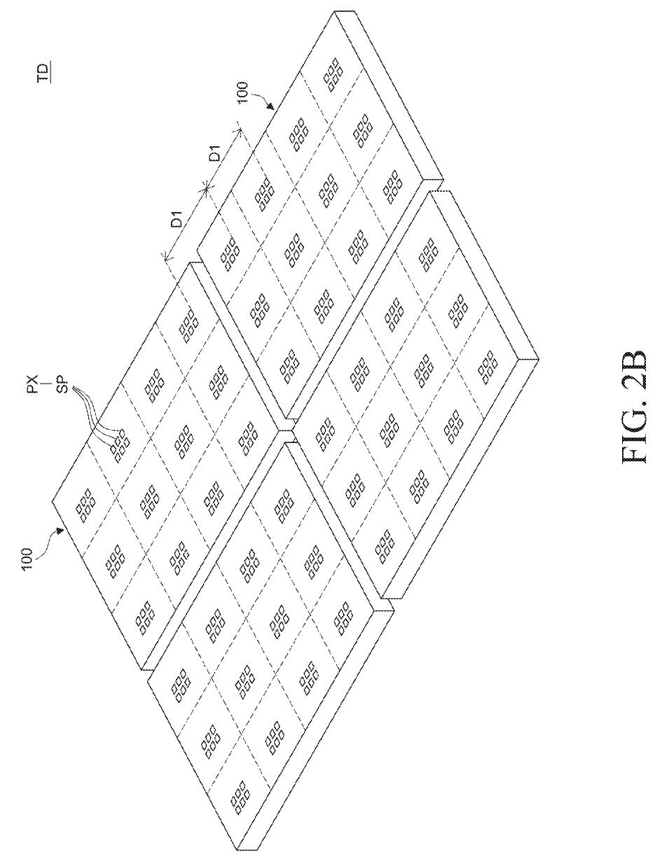

In contrast, when the gate driver GD is mounted in the display area AA in the GIA manner and a side line SRL which connects the signal line on the front surface of the display panel PN to the pad electrode on the rear surface of the display panel PN is formed to bond the flexible film and the printed circuit board to the rear surface of the display panel PN, the non-display area NA on the front surface of the display panel PN may be minimized or reduced. That is, when the gate driver GD, the data driver DD, and the timing controller TC are connected to the display panel PN as described above, a zero bezel in which there is substantially no bezel may be implemented, and a more detailed description will be described with reference to FIGS. 2A and 2B.

FIG. 2A is a partial cross-sectional view of a display device according to one or more embodiments of the present disclosure. FIG. 2B is a perspective view of a tiling display device according to one or more embodiments of the present disclosure.

In the non-display area NA of the display panel PN, a plurality of pad electrodes for transmitting various signals to the plurality of sub pixels SP is disposed. For example, a first pad electrode PAD1 for transmitting a signal to the plurality of sub pixels SP is disposed in the non-display area NA on the front surface of the display panel PN, and a second pad electrode PAD2 electrically connected to a driving component such as a flexible film and a printed circuit board is disposed in the non-display area NA on the rear surface of the display panel PN. In this case, although not illustrated in the drawings, various signal lines connected to the plurality of sub pixels SP, for example, a scan line SL or a data line DL extend from the display area AA to the non-display area NA to be electrically connected to the first pad electrode PAD1.

Further, the side line SRL is disposed along the side surface of the display panel PN. The side line SRL may electrically connect the first pad electrode PAD1 on the front surface of the display panel PN and the second pad electrode PAD2 on the rear surface of the display panel PN. Therefore, a signal from the driving component on the rear surface of the display panel PN may be transmitted to the plurality of sub pixels SP through the second pad electrode PAD2, the side line SRL, and the first pad electrode PAD1. Accordingly, a signal transmission path is formed from the front surface of the display panel PN to the side surface and the rear surface to minimize or reduce the area of the non-display area NA of the display panel PN.

Further, referring to FIG. 2B, a tiling display device TD having a large screen may be implemented by connecting a plurality of display devices 100. In this case, when the tiling display device TD is implemented using the display device 100 with a minimized or reduced bezel as illustrated in FIG. 2A, a seam area in which an image between the display device 100 and the display device 100 is not displayed is minimized or reduced, thereby improving the display quality.

For example, the plurality of sub pixels SP may form one pixel PX, and an interval D1 between an outermost pixel PX of one display device 100 and an outermost pixel PX of another display device 100 adjacent to one display device 100 may be implemented to be equal to an interval D1 between pixels PX in one display device 100. Accordingly, the distance between the pixels PX between the display device 100 and the display device 100 is constantly configured to minimize or reduce the seam area.

However, FIGS. 2A and 2B are illustrative so that the display device 100 according to one or more embodiments of the present disclosure may be a general display device with a bezel, but is not limited thereto.

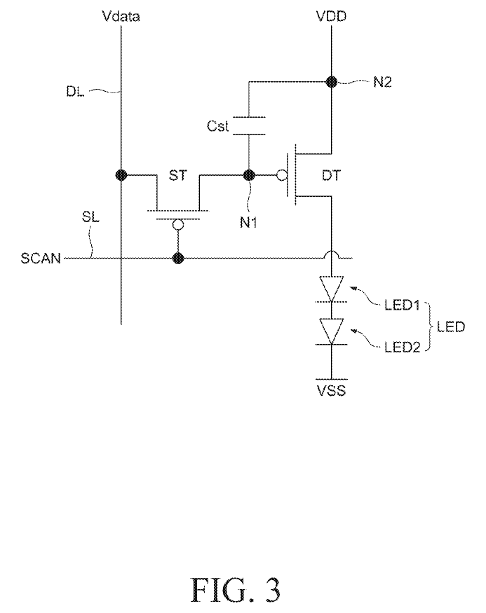

FIG. 3 is a circuit diagram of a sub pixel of a display device according to one or more embodiments of the present disclosure.

Referring to FIG. 3, a sub pixel circuit disposed in each of a plurality of sub pixels SP of a display device 100 according to one or more embodiments of the present disclosure may include a plurality of light emitting elements LED, a driving transistor DT, a switching transistor ST, and a capacitor Cst.

Meanwhile, in the N-type transistor, since carriers are electrons, electrons may flow from the source electrode to the drain electrode, and current may flow from the drain electrode to the source electrode. In the P-type transistor, since carriers are holes, holes may flow from the source electrode to the drain electrode, and current may flow from the source electrode to the drain electrode. For example, some of a plurality of transistors may be N-type transistors, and the others may be P-type transistors. Hereinafter, the description will be made on the assumption that both the driving transistor DT and the switching transistor ST are P-type transistors, but the present disclosure is not limited thereto.

The driving transistor DT may control a driving current applied to the light emitting element LED according to a source-gate voltage. The driving transistor DT may include a gate electrode connected to a drain electrode of the switching transistor ST, a source electrode connected to a high potential power line to which a high potential power voltage VDD is supplied, and a drain electrode connected to an anode electrode of a first light emitting element LED1 among the plurality of light emitting elements LED.

The switching transistor ST may apply a data voltage Vdata applied from the data line DL to the first node N1. The switching transistor ST may include a gate electrode connected to the scan line SL, a source electrode connected to the data line DL, and a drain electrode connected to the first node N1. Accordingly, the switching transistor ST may apply the data voltage Vdata from the data line DL to the first node N1 in response to the scan signal SCAN.

The capacitor Cst may include a first electrode connected to the first node N1 and a second electrode connected to the second node N2. That is, the first electrode of the capacitor Cst is connected to the gate electrode of the driving transistor DT, and the second electrode of the capacitor Cst is connected to the source electrode of the driving transistor DT. Accordingly, the capacitor Cst maintains a potential difference between the gate electrode and the source electrode of the driving transistor DT while the light emitting element LED emits light, so that a constant driving current may be supplied to the light emitting element LED.

The plurality of light emitting elements LED may include a first light emitting element LED1 and a second light emitting element LED2 which emit light of the same color.

The first light emitting element LED1 may include an anode electrode connected to the drain electrode of the driving transistor DT and a cathode electrode connected to the anode electrode of the second light emitting element LED2. The first light emitting element LED1 may emit light by receiving a driving current from the driving transistor DT.

The second light emitting element LED2 may be connected to the first light emitting element LED1 in series. The second light emitting element LED2 may include an anode electrode connected to the cathode electrode of the first light emitting element LED1 and a cathode electrode connected to a low potential power line to which a low potential power voltage VSS is supplied. The second light emitting element LED2 may emit light by receiving a driving current of the driving transistor DT through the first light emitting element LED1.

In the meantime, even though in FIG. 3, the sub pixel circuit is illustrated as a 2T1C structure including two transistors and one capacitor, the sub pixel circuit may be disposed in a 3T1C or 8T3C structure, but is not limited thereto.

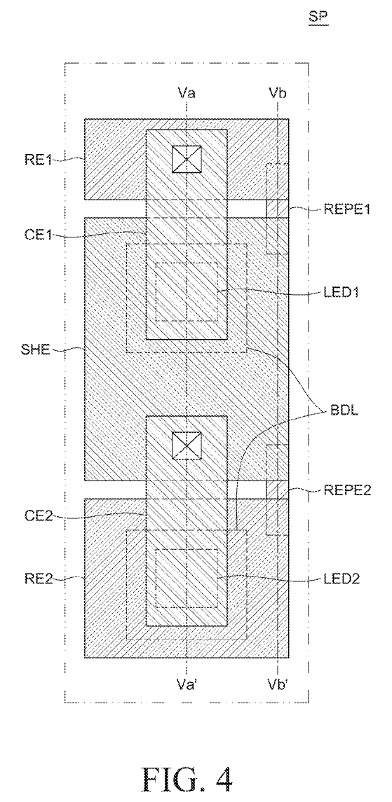

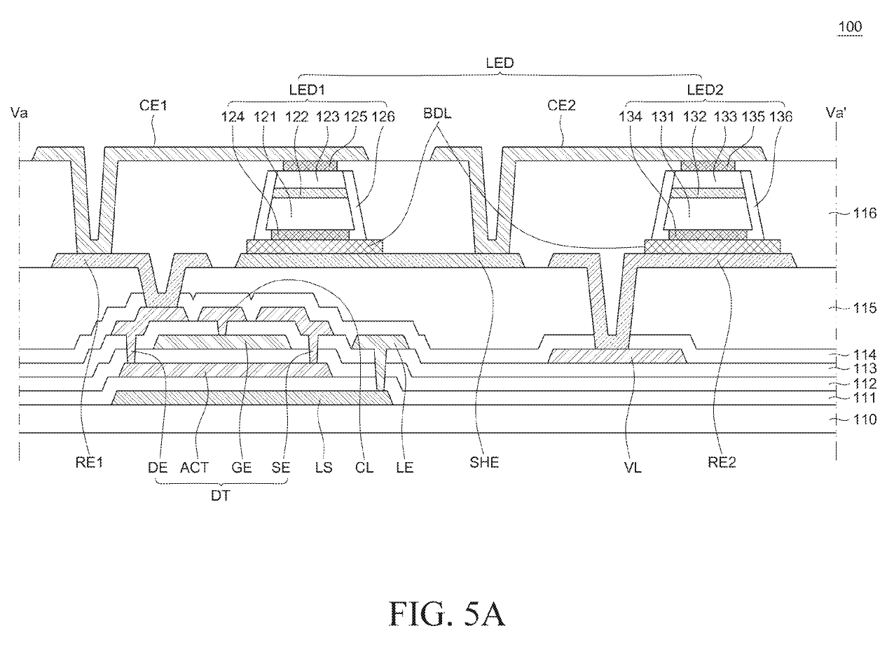

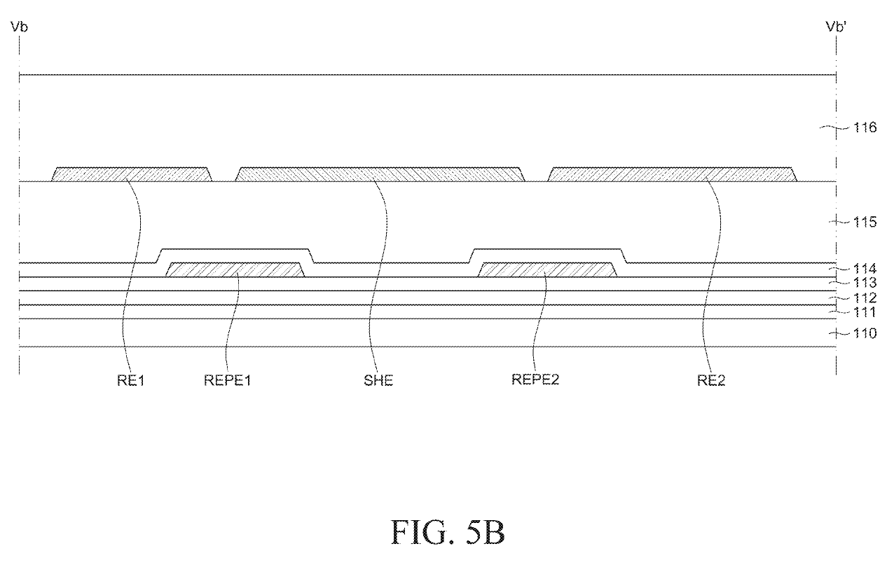

FIG. 4 is a plan view of a sub pixel of a display device according to one or more embodiments of the present disclosure. FIG. 5A is a cross-sectional view taken along the line Va-Va’ of FIG. 3. FIG. 5B is a cross-sectional view taken along the line Vb-Vb’ of FIG. 3.

First, referring to FIGS. 5A and 5B, the substrate 110 is a component for supporting various components included in the display device 100 and may be made of an insulating material. For example, the substrate 110 may be made of glass, resin, or the like. In addition, the substrate 110 may include polymer or plastic, or may be made of a material having flexibility.

The light shielding layer LS may be disposed in each of the plurality of sub pixels SP on the substrate 110. The light shielding layer LS blocks light incident onto an active layer ACT of the driving transistor DT to be described below from a lower portion of the substrate 110. Light which is incident onto the active layer ACT of the driving transistor DT is blocked by the light shielding layer LS to minimize or reduce a leakage current.

A buffer layer 111 may be disposed on the substrate 110 and the light shielding layer LS. The buffer layer 111 may reduce penetration of moisture or impurities through the substrate 110. For example, the buffer layer 111 may be configured as a single layer or multilayer made of silicon oxide (SiOx) or silicon nitride (SiNx). However, the present disclosure is not limited thereto.

The driving transistor DT may be disposed on the buffer layer 111. The driving transistor DT includes an active layer ACT, a gate electrode GE, a source electrode SE, and a drain electrode DE.

The active layer ACT may be disposed on the buffer layer 111. The active layer ACT may be formed of a semiconductor material such as an oxide semiconductor, amorphous silicon, or polysilicon, but is not limited thereto.

The gate insulating layer 112 may be disposed on the active layer ACT. The gate insulating layer 112 is an insulating layer which insulates the active layer ACT from the gate electrode GE and may be configured by a single layer or a double layer of silicon oxide (SiOx) or silicon nitride (SiNx), but is not limited thereto.

The gate electrode GE may be disposed on the gate insulating layer 112. The gate electrode GE may be configured by a conductive material such as copper (Cu), aluminum (Al), molybdenum (Mo), nickel (Ni), titanium (Ti), chromium (Cr), or an alloy thereof, but is not limited thereto.

The interlayer insulating layer 113 may be disposed on the gate electrode GE. A contact hole through which the source electrode SE and the drain electrode DE are connected to the active layer ACT is formed in the interlayer insulating layer 113. The interlayer insulating layer 113 is an insulating layer which protects components below the interlayer insulating layer 113 and may be configured by a single layer or a double layer of silicon oxide (SiOx) or silicon nitride (SiNx), but is not limited thereto.

The source electrode SE and the drain electrode DE which are electrically connected to the active layer ACT may be disposed on the interlayer insulating layer 113. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

Meanwhile, in the present disclosure, it has been described that one insulating layer is disposed between the gate electrode GE and the source electrode SE and the drain electrode DE. However, a plurality of insulating layers may be disposed between the gate electrode GE and the source electrode SE and the drain electrode DE, but is not limited thereto.

The auxiliary electrode LE may be disposed on the gate insulating layer 112. The auxiliary electrode LE is an electrode which electrically connects the light shielding layer LS below the buffer layer 111 to any one of the source electrode SE and the drain electrode DE on the interlayer insulating layer 113. For example, the light shielding layer LS is electrically connected to any one of the source electrode SE or the drain electrode DE through the auxiliary electrode LE so as not to operate as a floating gate. Therefore, fluctuation of a threshold voltage of the driving transistor DT caused by the floated light shielding layer LS may be minimized or reduced.

The power line VL may be disposed on the interlayer insulating layer 113. The power line VL is electrically connected to the light emitting element LED together with the driving transistor DT to allow the light emitting element LED to emit light. The power line VL may be a low potential power line which supplies a low potential power voltage VSS, but is not limited thereto and may be a high potential power line which supplies a high potential power voltage VDD. The power line VL may be configured by a conductive material such as copper (Cu), aluminum (Al), molybdenum (Mo), nickel (Ni), titanium (Ti), chrome (Cr), or an alloy thereof, but is not limited thereto.

The conductive layer CL may be disposed on the interlayer insulating layer 113. The conductive layer CL may connect the gate electrode GE of the driving transistor DT and another electrode. For example, the conductive layer CL may connect the gate electrode GE of the driving transistor DT and the drain electrode of the switching transistor ST, but is not limited thereto. The conductive layer CL may be made of a conductive material, for example, copper (Cu), aluminum (Al), molybdenum (Mo), nickel (Ni), titanium (Ti), chromium (Cr), or an alloy thereof, but is not limited thereto.

Referring to FIGS. 4 to 5B together, the first repair electrode REPE1 and the second repair electrode REPE2 may be disposed on the interlayer insulating layer 113. The first repair electrode REPE1 and the second repair electrode REPE2 are connected to the shared electrode SHE connecting the first light emitting element LED1 and the second light emitting element LED2 to form a path through which the current of the driving transistor DT or the power line VL detours. Therefore, even if any one of the first light emitting element LED1 and the second light emitting element LED2 connected in series is defective, the remaining one may be normally driven. The first repair electrode REPE1 and the second repair electrode REPE2 may be formed on the same layer as the source electrode SE and the drain electrode DE, and may be formed of the same material, but are not limited thereto. The first repair electrode REPE1 and the second repair electrode REPE2 may be disposed to be spaced apart from each other, but are not limited thereto.

When both the first light emitting element LED1 and the second light emitting element LED2 are normal, the second light emitting element LED2 is supplied with a driving current of the driving transistor DT through the first light emitting element LED1 which is connected to the second light emitting element LED2 in series. Likewise, the first light emitting element LED1 is supplied with the power current of the power line VL through the second light emitting element LED2.

At this time, when the first light emitting element LED1 is defective, the second light emitting element LED2 which is connected to the first light emitting element LED1 in series is not supplied with the driving current of the driving transistor DT through the first light emitting element LED1. Therefore, even if the second light emitting element LED2 is normal, the second light emitting element LED2 may not be turned on. Therefore, when the first light emitting element LED1 is defective, the first repair electrode REPE1 may be connected to the first reflective electrode RE1 and the shared electrode SHE to form a current path between the second light emitting element LED2 and the driving transistor DT.

For example, the first repair electrode REPE1 may be disposed between the first reflective electrode RE1 and the shared electrode SHE. In this case, at least a part of the first repair electrode REPE1 may be disposed to overlap the first reflective electrode RE1 and the shared electrode SHE. Accordingly, when the first light emitting element LED1 is defective, a welding process may be performed by irradiating an overlapping point between the first reflective electrode RE1 and the first repair electrode REPE1 and an overlapping point between the shared electrode SHE and the first repair electrode REPE1 by irradiating a laser, such that the first repair electrode REPE1 to contact the first reflective electrode RE1 and the shared electrode SHE. Accordingly, the first reflective electrode RE1 and the shared electrode SHE may be connected to each other through the first repair electrode REPE1. Therefore, the second light emitting element LED2 may be connected to the driving transistor DT through the shared electrode SHE, the first repair electrode REPE1, and the first reflective electrode RE1. Accordingly, even if the first light emitting element LED1 is defective, the second light emitting element LED2 may be normally turned on by receiving the driving current of the driving transistor DT.

Meanwhile, the shared electrode SHE connected to the first electrode 124 of the first light emitting element LED1 and the first reflective electrode RE1 connected to the second electrode 125 of the first light emitting element LED1 are connected to each other through a welding process. Therefore, the same voltage is applied to the first electrode 124 and the second electrode 125 of the first light emitting element LED1 to completely darken the first light emitting element LED1.

On the contrary, when the first light emitting element LED1 is normal, the first repair electrode REPE1 may be in a floating state that is not connected to any other electrode including the first reflective electrode RE1 and the shared electrode SHE.

When the second light emitting element LED2 is defective, the first light emitting element LED1 connected to the second light emitting element LED2 in series is not supplied with the power current of the power line VL through the second light emitting element LED2. Therefore, even if the first light emitting element LED1 is normal, the first light emitting element LED1 may not be turned on. Therefore, when the second light emitting element LED2 is defective, the second repair electrode REPE2 may be connected to the second reflective electrode RE2 and the shared electrode SHE to form a current path between the first light emitting element LED1 and the power line VL.

For example, the second repair electrode REPE2 may be disposed between the shared electrode SHE and the second reflective electrode RE2. In this case, at least a part of the second repair electrode REPE2 may be disposed to overlap the shared electrode SHE and the second reflective electrode RE2. Therefore, when the second light emitting element LED2 is defective, a welding process may be performed by irradiating an overlapping point of the shared electrode SHE and the second repair electrode REPE2 and an overlapping point of the second reflective electrode RE2 and the second repair electrode REPE2 with laser beams, such that the second repair electrode REPE2 may be in contact with the second reflective electrode RE2 and the shared electrode SHE. Accordingly, the second reflective electrode RE2 and the shared electrode SHE may be connected to each other through the second repair electrode REPE2. Therefore, the first light emitting element LED1 may be connected to the power line VL through the shared electrode SHE, the second repair electrode REPE2, and the second reflective electrode RE2. Accordingly, even if the second light emitting element LED2 is defective, the first light emitting element LED1 may be normally turned on by receiving the power current of the power line VL.

Meanwhile, the second reflective electrode RE2 connected to the first electrode 134 of the second light emitting element LED2 and the shared electrode SHE connected to the second electrode 135 of the second light emitting element LED2 are connected to each other through a welding process. Therefore, the same voltage is applied to the first electrode 134 and the second electrode 135 of the second light emitting element LED2 to completely darken the second light emitting element LED2.

On the contrary, when the second light emitting element LED2 is normal, the second repair electrode REPE2 may be in a floating state that is not connected to any other electrode including the second reflective electrode RE2 and the shared electrode SHE.

For example, the first repair electrode REPE1 and the second repair electrode REPE2 may be disposed on the same layer and made of the same material as the source electrode SE and the drain electrode DE of the driving transistor DT, but are not limited thereto.

Meanwhile, in order to prevent the driving transistor DT disposed on the same layer from being welled together during the welding process of the first repair electrode REPE1 and the second repair electrode REPE2, the first repair electrode REPE1 and the second repair electrode REPE2 may be disposed so as not to overlap the driving transistor DT, but is not limited thereto.

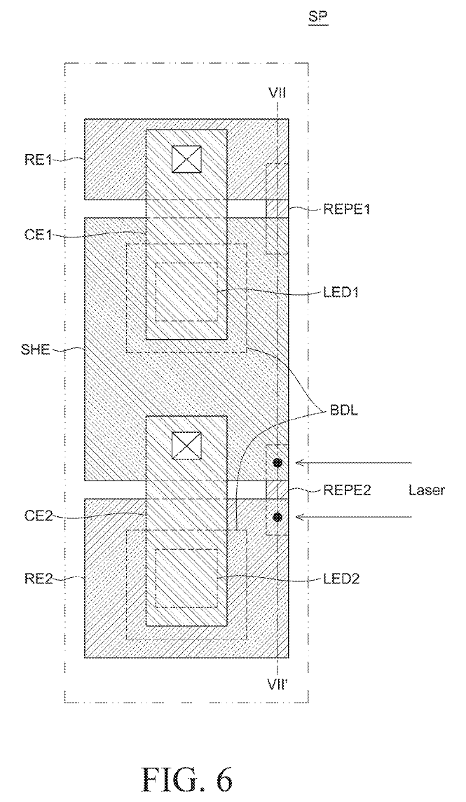

A method of repairing the light emitting element LED through a welding process of the first repair electrode REPE1 and the second repair electrode REPE2 will be described in detail with reference to FIGS. 6 to 9 to be described below.

The passivation layer 114 may be disposed on the first repair electrode REPE1, the second repair electrode REPE2, the conductive layer CL, the driving transistor DT, and the power line VL. The passivation layer 114 may protect the conductive layer CL, the driving transistor DT, and the power line VL from penetration of moisture or impurities. For example, the passivation layer 114 may be configured as a single layer or multilayer made of silicon oxide (SiOx) or silicon nitride (SiNx). However, the present specification is not limited thereto.

The first planarization layer 115 may be disposed on the passivation layer 114. The first planarization layer 115 may planarize an upper portion of the substrate 110 on which the driving transistor DT is disposed. The first planarization layer 115 may be configured by a single layer or a double layer, and for example, may be formed of photoresist or an acrylic-based organic material, but is not limited thereto and may be configured by an inorganic material including silicon such as silicon oxide (SiOx) or silicon nitride (SiNx).

The first reflective electrode RE1 and the second reflective electrode RE2 which are spaced apart from each other may be disposed on the first planarization layer 115. The first reflective electrode RE1 and the second reflective electrode RE2 electrically connect the light emitting element LED to the power line VL and the driving transistor DT, and simultaneously, may serve as a reflective plate that reflects light emitted from the light emitting element LED to the upper portion of the light emitting element LED. The first reflective electrode RE1 and the second reflective electrode RE2 are formed of a conductive material having excellent reflection characteristics to reflect light emitted from the light emitting element LED toward the upper portion of the light emitting element LED.

The first reflective electrode RE1 may electrically connect the driving transistor DT and the first light emitting element LED1. The first reflective electrode RE1 may be connected to the drain electrode DE of the driving transistor DT through a contact hole formed in the passivation layer 114 and the first planarization layer 115. Further, the first reflective electrode RE1 may be electrically connected to the second electrode 125 of the first light emitting element LED1 through the first connection electrode CE1.

The second reflective electrode RE2 may electrically connect the power line VL and the second light emitting element LED2. The second reflective electrode RE2 may be connected to the power line VL through a contact hole formed in the passivation layer 114 and the first planarization layer 115, and may be electrically connected to the first electrode 134 of the second light emitting element LED through a bonding layer BDL to be described below.

The shared electrode SHE may be disposed on the first planarization layer 115 to be spaced apart from the first reflective electrode RE1 and the second reflective electrode RE2. For example, the shared electrode SHE may be disposed between the first reflective electrode RE1 and the second reflective electrode RE2. The shared electrode SHE may electrically connect the first light emitting element LED1 and the second light emitting element LED2. For example, the shared electrode SHE may be connected to the first light emitting element LED1 through the bonding layer BDL disposed on the shared electrode SHE. For example, the shared electrode SHE may be connected to the first electrode 124 of the first light emitting element LED1. Further, the shared electrode SHE may be connected to the second electrode 135 of the second light emitting element LED2 through a second connection electrode CE2 to be described below.

The shared electrode SHE may be disposed on the same layer with the same material as the first reflective electrode RE1 and the second reflective electrode RE2. Therefore, like the first reflective electrode RE1 and the second reflective electrode RE2, the shared electrode SHE is formed of a conductive material having excellent reflective properties to reflect light emitted from the light emitting element LED toward the upper portion of the light emitting element LED, but is not limited thereto.

A plurality of bonding layers BDL may be disposed on the shared electrode SHE and the second reflective electrode RE2, respectively. The bonding layer BDL may fix the light emitting element LED disposed on the shared electrode SHE and the second reflective electrode RE2. The bonding layer BDL may be formed of a conductive material to electrically connect the shared electrode SHE and the first electrode 124 and the second reflective electrode RE2 of the first light emitting element LED1 and the first electrode 134 of the second light emitting element LED2, respectively, but is not limited thereto.

A plurality of light emitting elements LED may be disposed on the plurality of bonding layers BDL, respectively. The plurality of light emitting elements LED is an element which emits light by a current and may include a light emitting element LED which emits red light, green light, and blue light and may implement various colored light including white by a combination thereof. For example, the plurality of light emitting elements LED may be micro-LEDs, but is not limited thereto.

The plurality of light emitting elements LED may include a first light emitting element LED1 and a second light emitting element LED2 which are connected in series. The first light emitting element LED1 and the second light emitting element LED2 may emit light of the same color.

For example, the first light emitting element LED1 may be disposed on the bonding layer BDL disposed on the shared electrode SHE, and the second light emitting element LED2 may be disposed on the bonding layer BDL disposed on the second reflective electrode RE2. Therefore, the first light emitting element LED1 may be electrically connected to the shared electrode SHE through the bonding layer BDL, and the second light emitting element LED2 may be electrically connected to the second reflective electrode RE2 through the bonding layer BDL.

The first light emitting element LED1 may include a first semiconductor layer 121, an emission layer 122, a second semiconductor layer 123, a first electrode 124, a second electrode 125, and a passivation film 126. Specifically, the first electrode 124 may be disposed on the bonding layer BDL disposed on the shared electrode SHE. The first electrode 124 is an electrode for electrically connecting the second electrode 135 of the second light emitting element LED2 and the first semiconductor layer 121 through the bonding layer BDL, the shared electrode SHE, and the second connection electrode CE2. In this case, the first semiconductor layer 121 may be a semiconductor layer doped with an n-type impurity, and the first electrode 124 may be a cathode. The first electrode 124 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The first semiconductor layer 121 may be disposed on the first electrode 124. The second semiconductor layer 123 may be disposed on the first semiconductor layer 121. The first semiconductor layer 121 and the second semiconductor layer 123 may be layers formed by doping n-type or p-type impurities into a specific material. For example, each of the first semiconductor layer 121 and the second semiconductor layer 123 may be layers doped with n-type and p-type impurities into a material such as gallium nitride (GaN), indium aluminum phosphide (InAlP), or gallium arsenide (GaAs).

The emission layer 122 may be disposed between the first semiconductor layer 121 and the second semiconductor layer 123. The emission layer 122 may receive holes and electrons from the first semiconductor layer 121 and the second semiconductor layer 123 to emit light.

The second electrode 125 may be disposed on the second semiconductor layer 123. The second electrode 125 is an electrode which electrically connects the driving transistor DT and the second semiconductor layer 123. In this case, the second semiconductor layer 123 may be a semiconductor layer doped with a p-type impurity, and the second electrode 125 may be an anode. The second electrode 125 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the passivation film 126 may be disposed to surround the first semiconductor layer 121, the emission layer 122, the second semiconductor layer 123, and the second electrode 125. The passivation film 126 may be formed of an insulating material to protect the first semiconductor layer 121, the emission layer 122, and the second semiconductor layer 123.

Meanwhile, FIG. 5A illustrates that the passivation film 126 is disposed to be spaced apart from the second electrode 125. However, the present disclosure is not limited thereto. The passivation film 126 may be disposed to cover and surround a part of a top surface and a side surface of the second electrode 125, but is not limited to the one illustrated in the drawing.

Like the first light emitting element LED1, the second light emitting element LED2 may include a first semiconductor layer 131, an emission layer 132, a second semiconductor layer 133, a first electrode 134, a second electrode 135, and a passivation film 136. The shape of the second light emitting element LED2 and the arrangement structure of each component may be substantially the same as the shape of the first light emitting element LED1 and the arrangement structure of each component, and accordingly, a redundant description will be omitted.

The second planarization layer 116 may be disposed to surround the plurality of light emitting elements LED. The second planarization layer 116 may fix and protect the plurality of light emitting elements LED. Meanwhile, the second planarization layer 116 may be disposed to expose the second electrode 125 of the first light emitting element LED1 and the second electrode 135 of the second light emitting element LED2 and electrically connect the first connection electrode CE1 and the second connection electrode CE2, respectively, to be described below.

The second planarization layer 116 may be configured as a single layer or multilayer and made of benzocyclobutene (BCB) or an acrylic-based organic material, for example. However, the present disclosure is not limited thereto.

The first connection electrode CE1 and the second connection electrode CE2 may be disposed to be spaced apart from each other on the second planarization layer 116. The first connection electrode CE1 is an electrode for electrically connecting the first light emitting element LED1 and the driving transistor DT. The first connection electrode CE1 may be connected to the first reflective electrode RE1 through a contact hole formed in the second planarization layer 116. Accordingly, the first connection electrode CE1 may be connected to the driving transistor DT through the first reflective electrode RE1. For example, the first connection electrode CE1 may connect the second electrode 125 of the first light emitting element LED1 and the drain electrode DE of the driving transistor DT, but is not limited thereto.

The second connection electrode CE2 is an electrode for electrically connecting the second light emitting element LED2 to the shared electrode SHE. The second connection electrode CE2 may be connected to the shared electrode SHE through a contact hole formed in the second planarization layer 116. Accordingly, the second connection electrode CE2 may connect the second electrode 135 of the second light emitting element LED2 to the shared electrode SHE, but is not limited thereto.

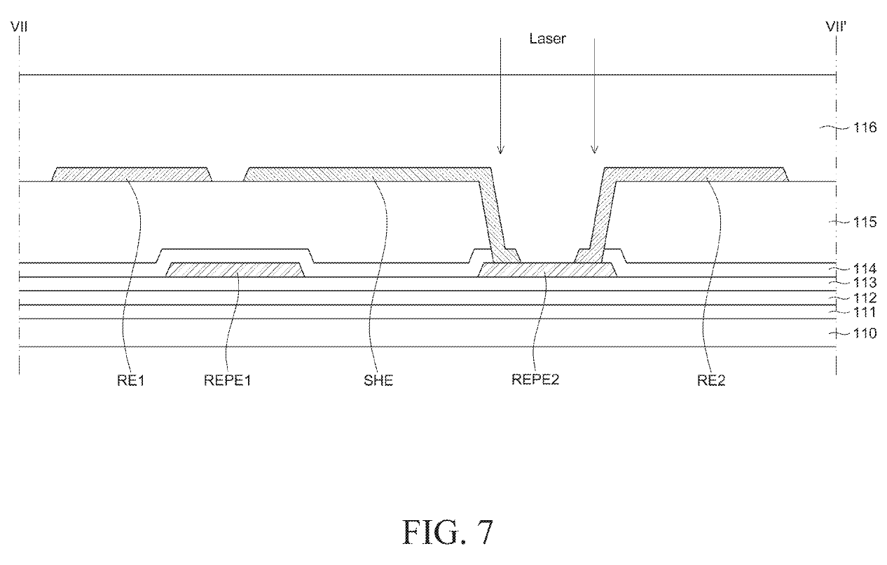

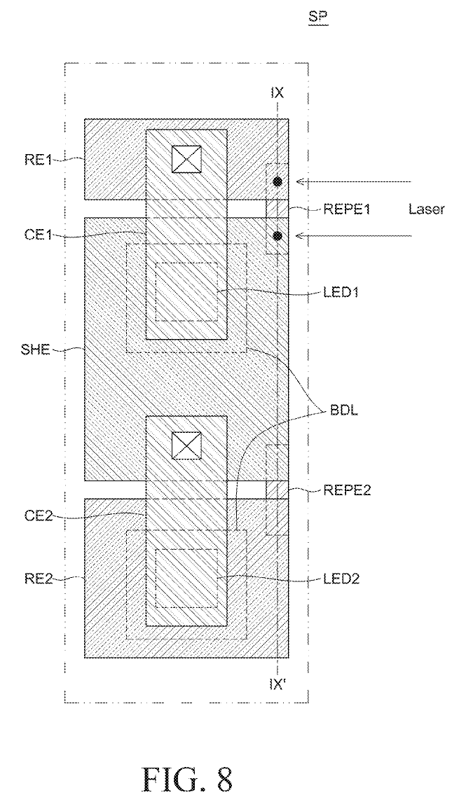

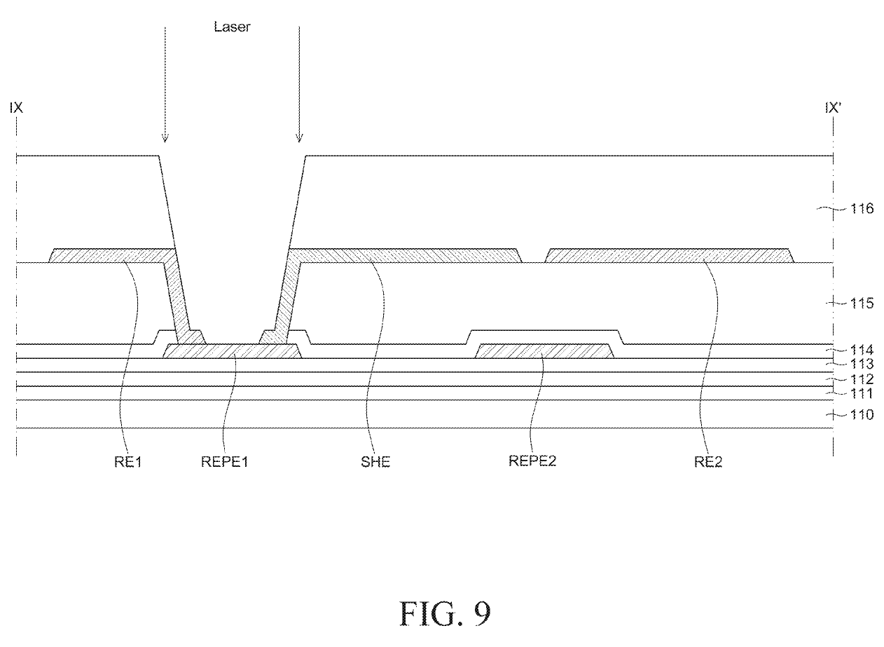

FIG. 6 is a plan view of a sub pixel of a display device according to one or more embodiments of the present disclosure. FIG. 7 is a cross-sectional view taken along the line VII-VII' of FIG. 6. FIG. 8 is a plan view of a sub pixel of a display device according to one or more embodiments of the present disclosure. FIG. 9 is a cross-sectional view taken along the line IX-IX' of FIG. 8. Specifically, FIGS. 6 and 7 are views for explaining a repair method when the second light emitting element LED2 is defective among the plurality of light emitting elements LED, and FIGS. 8 and 9 are views for explaining a repair method when the first light emitting element LED1 is defective among the plurality of light emitting elements LED.

In the display device 100 according to one or more embodiments of the present disclosure, when any one of the plurality of light emitting elements LED is defective, the welding process is performed on the shared electrode SHE connecting the plurality of light emitting elements LED and the first reflective electrode RE1 or the second reflective electrode RE2 to drive the other one normally, thereby minimizing or reducing the defect in which the corresponding sub pixel SP is completely darkened.

Meanwhile, since the possibility that both the first light emitting element LED1 and the second light emitting element LED2 are defective is remarkably low, it will be assumed and described hereinafter that if one of the light emitting elements LED is found to be defective, the other is normal, and thus a lighting test for the other is unnecessary.

First, referring to FIGS. 6 and 7, a lighting test of the second light emitting element LED2 may be performed before the process of forming the second planarization layer 116, the first connection electrode CE1, and the second connection electrode CE2. Since the first electrode 134 of the second light emitting element LED2 is connected to the power line VL through the second reflective electrode RE2, a lighting test may be performed by applying a lighting test signal to the second electrode 135 through the power line VL and to the second electrode 135 through a probe. When the second light emitting element LED2 is defective as a result of the lighting test, a welding process may be performed by irradiating an overlapping point of the shared electrode SHE and the second repair electrode REPE2 and an overlapping point of the second reflective electrode RE2 and the second repair electrode REPE2 with laser beams, such that the second repair electrode REPE2 may be in contact with the second reflective electrode RE2 and the shared electrode SHE.

Specifically, referring to FIG. 7, when the shared electrode SHE and the second reflective electrode RE2 are irradiated with laser beams, the passivation layer 114 and the first planarization layer 115 between the shared electrode SHE and the second reflective electrode RE2 and the second repair electrode REPE2 may be opened, and portions of the shared electrode SHE and the second reflective electrode RE2 may be melted, and the shared electrode SHE and the second reflective electrode RE2 may be connected to the second repair electrode REPE2.

Accordingly, the second reflective electrode RE2 and the shared electrode SHE may be electrically connected through the second repair electrode REPE2. Therefore, the second reflective electrode RE2 connected to the first electrode 134 of the second light emitting element LED2 and the shared electrode SHE connected to the second electrode 135 of the second light emitting element LED2 are connected to each other so that the same voltage is applied to the first electrode 134 and the second electrode 135 of the second light emitting element LED2. Therefore, the second light emitting element LED2 may be completely darkened.

Thereafter, the second planarization layer 116, the first connection electrode CE1, and the second connection electrode CE2 are formed to turn on only the first light emitting element LED1. For example, when both the first light emitting element LED1 and the second light emitting element LED2 are normal, the first light emitting element LED1 is connected to the power line VL through the second light emitting element LED2. However, since the shared electrode SHE is connected to the second reflective electrode RE2 through the second repair electrode REPE2 through the welding process, the first light emitting element LED1 may be connected to the power line VL through the shared electrode SHE, the second repair electrode REPE2, and the second reflective electrode RE2. That is, even though the second light emitting element LED2 which is connected to the first light emitting element LED1 in series is defective, a current path between the first light emitting element LED1 and the power line VL may be formed through the shared electrode SHE and the second repair electrode REPE2. Therefore, even though the power current detours to the first light emitting element LED1 and the second light emitting element LED2 connected in series with the first light emitting element LED1 is defective, the first light emitting element LED1 may be normally driven.

In this case, since the first light emitting element LED1 is normal, the first repair electrode REPE1 may be in a floating state that is not connected to any other electrode including the first reflective electrode RE1 and the shared electrode SHE.

Meanwhile, although not illustrated in the drawings, when the second light emitting element LED2 is defective, a repair method of removing the defective second light emitting element LED2 and transferring the new second light emitting element LED2 again may be used, rather than a welding process of the shared electrode SHE and the second reflective electrode RE2. For example, the second light emitting element LED2 may be removed together with the bonding layer BDL by irradiating the bonding layer BDL disposed below the second light emitting element LED2 with laser beams. Subsequently, a new bonding layer BDL and a new second light emitting element LED2 may be transferred onto the second reflective electrode RE2, but are not limited thereto.

Referring to FIGS. 8 and 9, as described above, since there are significantly less cases where both the first light emitting element LED1 and the second light emitting element LED2 are defective, as a result of the lighting test of the second light emitting element LED2, the lighting test of the first light emitting element LED1 may be performed only when the second light emitting element LED2 is normal.

Unlike the lighting test of the second light emitting element LED2, the lighting test of the first light emitting element LED1 may be performed after the lighting test of the second light emitting element LED2 and after the second planarization layer 116, the first connection electrode CE1, and the second connection electrode CE2 are all formed.

As a result of illumination inspection of the first light emitting element LED1, a welding process may be performed by irradiating an overlapping point between the first reflective electrode RE1 and the first repair electrode REPE1 and an overlapping point between the shared electrode SHE and the first repair electrode REPE1 by irradiating a laser, such that the first repair electrode REPE1 contacts the first reflective electrode RE1 and the shared electrode SHE.

Specifically, referring to FIG. 9, when the shared electrode SHE and the first reflective electrode RE1 are irradiated with laser beams, a second planarization layer 116 disposed on the shared electrode SHE and the first reflective electrode RE1 and a passivation layer 114 and the first planarization layer 115 between the shared electrode SHE and the first reflective electrode RE1 and the first repair electrode REPE1 may be opened, a part of the shared electrode SHE and the first reflective electrode RE1 may melt, and the shared electrode SHE and the first reflective electrode RE1 may be connected to the first repair electrode REPE1. FIG. 9 illustrates that the second planarization layer 116 is opened by laser irradiation, but is not limited thereto. The second planarization layer 116 is not opened and maintains the same shape as FIG. 7, and the passivation layer 114 and the first planarization layer 115 between the shared electrode SHE and the first reflective electrode RE1 and the first repair electrode REPE1 are opened, such that the shared electrode SHE and the first reflective electrode RE1 may be connected to the first repair electrode REPE1.

Accordingly, the first reflective electrode RE1 and the shared electrode SHE may be connected to each other through the first repair electrode REPE1. Therefore, the shared electrode SHE connected to the first electrode 124 of the first light emitting element LED1 and the first reflective electrode RE1 connected to the second electrode 125 of the first light emitting element LED1 are connected to each other, such that the same voltage is applied to the first electrode 124 and the second electrode 125 of the first light emitting element LED1, so the first light emitting element LED1 may be completely darkened.

Therefore, only the second light emitting element LED2 may be turned on. For example, when both the first light emitting element LED1 and the second light emitting element LED2 are normal, the second light emitting element LED2 is connected to the driving transistor DT through the first light emitting element LED1. However, since the shared electrode SHE is connected to the first reflective electrode RE1 through the first repair electrode REPE1, the second light emitting element LED2 may be connected to the driving transistor DT through the shared electrode SHE, the first repair electrode REPE1, and the first reflective electrode RE1. That is, a current path between the second light emitting element LED2 and the driving transistor DT may be formed through the shared electrode SHE and the first repair electrode REPE1. Therefore, even though the driving current detours to the second light emitting element LED2 and the first light emitting element LED1 connected to the second light emitting element LED2 in series is defective, the second light emitting element LED2 may be normally driven.

In this case, since the second light emitting element LED2 is normal, the second repair electrode REPE2 may be in a floating state that is not connected to any other electrode including the second reflective electrode RE2 and the shared electrode SHE.

Meanwhile, since the lighting test of the first light emitting element LED1 is performed after the formation of the first connection electrode CE1 and the second connection electrode CE2, when the first light emitting element LED1 is defective, a repair method of removing the defective first light emitting element LED1 and transferring the new first light emitting element LED1 may be difficult to use, but is not limited thereto.

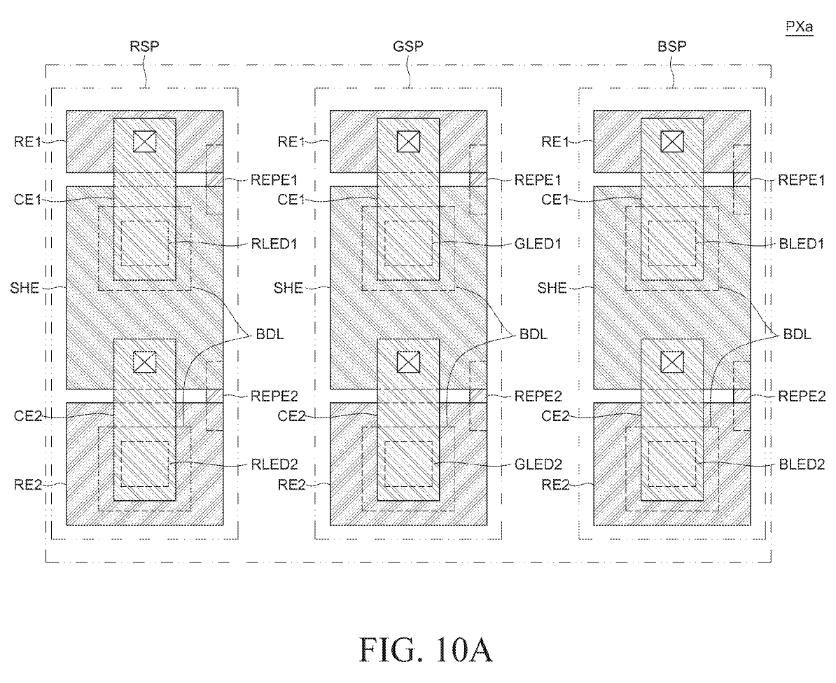

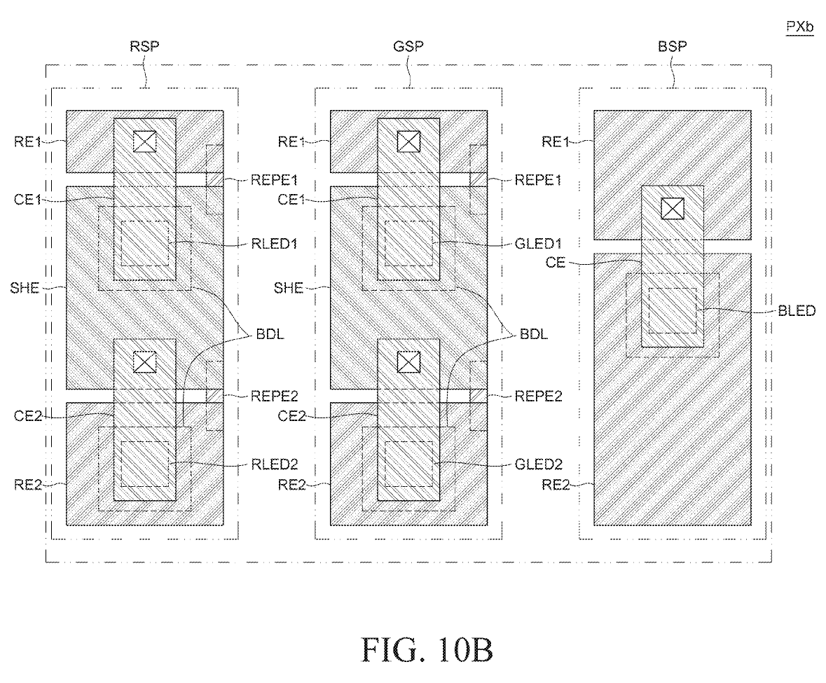

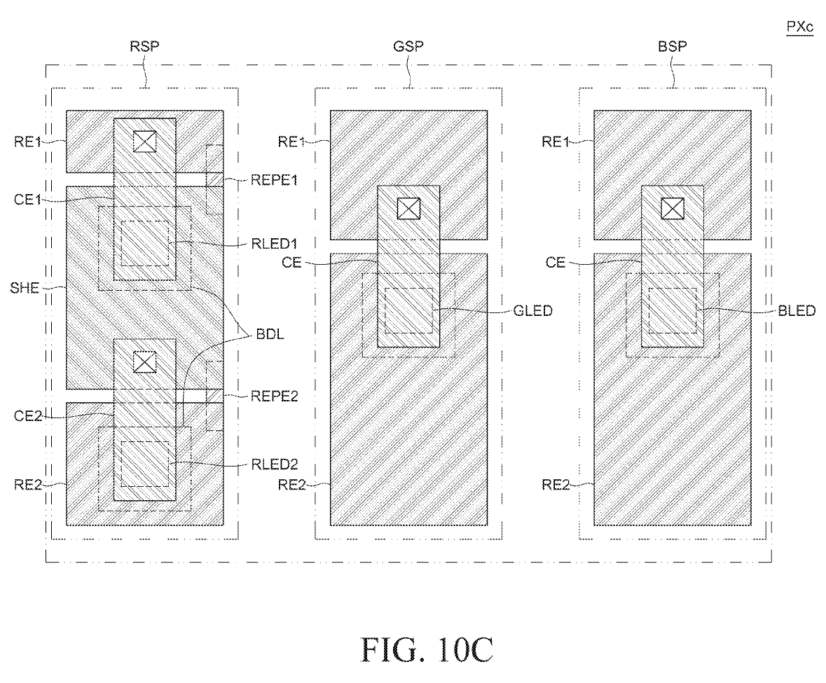

FIGS. 10A to 10C are plan views of a pixel of a display device according to one or more embodiments of the present disclosure. FIGS. 10A to 10C are views for explaining that the series connection structure of the light emitting element LED of FIGS. 1 to 9 and the repair structure using the first repair electrode REPE1 and the second repair electrode REPE2 may be selectively applied to some sub pixels SP. For example, the series connection structure of the light emitting element LED and the repair structure using the first repair electrode REPE1 and the second repair electrode REPE2 are applied only to all sub pixels SP of the pixel PXa and the red sub pixels RSP of the pixel PXb and the green sub pixels GSP of the pixel PXc as shown in FIG. 10A.

Referring to FIGS. 10A to 10C, the pixels PXa, PXb, and PXc may include one red sub pixel RSP configured to emit red light, one green sub pixel GSP configured to emit green light, and one blue sub pixel BSP configured to emit blue light.

Referring to FIGS. 10A to 10C, a plurality of red light emitting elements RLED1 and RLED2 may be disposed in the red sub pixels RSP disposed in each of the pixels PXa, PXb, and PXc. For example, a first red light emitting element RLED1 and a second red light emitting element RLED2 which are connected in series may be disposed in the red sub pixel RSP. In general, the red light emitting elements RLED1 and RLED2 have higher power consumption than the green light emitting elements GLED, GLED1, and GLED2 and the blue light emitting elements BLED, BLED1, and BLED2. Therefore, the first red light emitting element RLED1 and the second red light emitting element RLED2 which are connected in series are disposed in the red sub pixel RSP to reduce power consumption.

Referring to FIGS. 10A and 10B, a plurality of green light emitting elements GLED1 and GLED2 may be disposed in the green sub pixel GSP. For example, a first green light emitting element GLED1 and a second green light emitting element GLED2 which are connected in series may be disposed in the green sub pixel GSP. Since the green light emitting elements GLED, GLED1, and GLED2 have higher power consumption than the blue light emitting elements BLED, BLED1, and BLED2, the first green light emitting element GLED1 and the second green light emitting element GLED2 connected in series are disposed in the green sub pixel GSP to reduce power consumption.

However, the present disclosure is not limited thereto. Referring to FIG. 10C, one green light emitting element GLED may be disposed in the green sub pixel GSP. When only one green light emitting element GLED is disposed as described above, the green light emitting element GLED may be disposed on the second reflective electrode RE2, and the shared electrode SHE, the first repair electrode REPE1, and the second repair electrode REPE2 may not be disposed. Therefore, only one connection electrode CE is also disposed to connect the first reflective electrode RE1 and the green light emitting element GLED, but is not limited thereto.

Referring to FIG. 10A, a plurality of blue light emitting elements BLED1 and BLED2 may be disposed in the blue sub pixel BSP. For example, a first blue light emitting element BLED1 and a second blue light emitting element BLED2 which are connected in series may be disposed in the blue sub pixel BSP. Accordingly, the first blue light emitting element BLED1 and the second blue light emitting element BLED2 connected in series are disposed to reduce power consumption.

However, the present disclosure is not limited thereto. Referring to FIGS. 10B and 10C, the blue light emitting element BLED has better power consumption efficiency than the red light emitting elements RLED1 and RLED2 and the green light emitting elements GLED, GLED1, and GLED2 described above, so one blue light emitting element BLED may be disposed in the blue sub pixel BSP. When only one blue light emitting element BLED is disposed as described above, the blue light emitting element BLED may be disposed on the second reflective electrode RE2, and the shared electrode SHE, the first repair electrode REPE1, and the second repair electrode REPE2 may not be disposed. Therefore, only one connection electrode CE is also disposed to connect the first reflective electrode RE1 and the blue light emitting element BLED, but is not limited thereto.

That is, referring to FIGS. 10A to 10C, the light emitting elements LED connected in series may be disposed in some of the sub pixels SP in consideration of the power consumption efficiency of each sub pixel SP. However, the present disclosure is not limited thereto. The series connection structure of the light emitting element LED and the repair structure through the shared electrode SHE and the first repair electrode REPE1 and the second repair electrode REPE2 may be applied to all sub pixels SP, which may be designed in various ways in consideration of the power consumption and arrangement of the sub pixels SP.

Various methods are being studied to implement a high-resolution and high-luminance display device without significantly increasing power consumption. For example, a plurality of light emitting elements connected in series to one sub pixel may be disposed. However, when a plurality of light emitting elements are connected to each other in series, if any one is defective, it may be difficult to drive the remaining light emitting elements. Therefore, an efficient arrangement structure in consideration of the repair of the light emitting element is particularly important.

In the display device 100 according to one or more embodiments of the present disclosure, the first light emitting element LED1 and the second light emitting element LED2 which are connected to each other in series may be disposed in one sub pixel SP. For example, the first light emitting element LED1 and the second light emitting element LED2 may be connected through the shared electrode SHE. Specifically, the second electrode 125 of the first light emitting element LED1 may be connected to the driving transistor DT, the first electrode 134 of the second light emitting element LED2 may be connected to the power line VL, and the shared electrode SHE may connect the first electrode 124 of the first light emitting element LED1 and the second electrode 135 of the second light emitting element LED2. Therefore, the first light emitting element LED1 may be connected to the power line VL through the second light emitting element LED2, and the second light emitting element LED2 may be connected to the driving transistor DT through the first light emitting element LED1. As described above, the first light emitting element LED1 and the second light emitting element LED2 are connected in series to reduce the current flowing through each sub pixel SP, thereby reducing power consumption.

Specifically, in the display device 100 according to one or more embodiments of the present disclosure, the shared electrode SHE connecting the first light emitting element LED1 and the second light emitting element LED2 is connected to the first repair electrode REPE1 or the second repair electrode REPE2 to form a path through which the current of the driving transistor DT or the power line VL detours. Therefore, even though any one of the first light emitting element LED1 and the second light emitting element LED2 connected in series is defective, the remaining one may be normally driven. For example, in the display device 100 according to one or more embodiments of the present disclosure, when the first light emitting element LED1 is defective, a welding process may be performed by irradiating an overlapping point between the first reflective electrode RE1 and the first repair electrode REPE1 and an overlapping point between the shared electrode SHE and the first repair electrode REPE1 to connect the first reflective electrode RE1 and the shared electrode SHE to each other through the first repair electrode REPE1. That is, because the shared electrode SHE is connected to the first reflective electrode RE1 through the first repair electrode REPE1, the normal second light emitting element LED2 may be connected to the driving transistor DT through the shared electrode SHE, the first repair electrode REPE1, and the first reflective electrode RE1. That is, even though the first light emitting element LED1 which is connected to the second light emitting element LED2 in series is defective, a current path between the second light emitting element LED2 and the driving transistor DT may be formed through the shared electrode SHE and the first repair electrode REPE1. Accordingly, the driving current detours to the second light emitting element LED2, and the second light emitting element LED2 may be normally driven. Accordingly, it is possible to minimize or reduce a defect in which the sub pixels SP are completely darkened. Further, the shared electrode SHE connected to the first electrode 124 of the first light emitting element LED1 and the first reflective electrode RE1 connected to the second electrode 125 of the first light emitting element LED1 are connected so that the same voltage is applied to the first electrode 124 and the second electrode 125 of the first light emitting element LED1 to completely darken the first light emitting element LED1.

Similarly, in the display device 100 according to one or more embodiments of the present disclosure, when the second light emitting element LED2 is defective, a welding process may be performed by irradiating an overlapping point between the second reflective electrode RE2 and the second repair electrode REPE2 and an overlapping point between the shared electrode SHE and the second repair electrode REPE2 to connect the second reflective electrode RE2 and the shared electrode SHE to each other through the second repair electrode REPE2. That is, because the shared electrode SHE is connected to the second reflective electrode RE2 through the second repair electrode REPE2, the normal first light emitting element LED1 may be connected to the power line VL through the shared electrode SHE, the second repair electrode REPE2, and the second reflective electrode RE2. That is, even though the second light emitting element LED2 which is connected to the first light emitting element LED1 in series is defective, a current path between the first light emitting element LED1 and the power line VL may be formed through the shared electrode SHE and the second repair electrode REPE2. Therefore, the power current detours to the first light emitting element LED1, and the first light emitting element LED1 may be normally driven. Accordingly, it is possible to minimize or reduce a defect in which the sub pixels SP are completely darkened. Further, the second reflective electrode RE2 connected to the first electrode 134 of the second light emitting element LED2 and the shared electrode SHE connected to the second electrode 135 of the second light emitting element LED2 are connected so that the same voltage is applied to the first electrode 134 and the second electrode 135 of the second light emitting element LED2 so that the second light emitting element LED2 may be completely darkened.

In the display device 100 according to one or more embodiments of the present disclosure, the series connection structure of the light emitting element LED and the repair structure through the first repair electrode REPE1 and the second repair electrode REPE2 may be selectively applied in consideration of power consumption efficiency of each sub pixel SP. For example, a plurality of light emitting elements LED connected in series to only a relatively low red sub pixel RSP may be disposed, and only one light emitting element LED may be disposed in each of the green sub pixel GSP and the blue sub pixel BSP. Therefore, the repair structure using the first repair electrode REPE1 and the second repair electrode REPE2 may also be applied only to the red sub pixel RSP. However, the present disclosure is not limited thereto. A plurality of light emitting elements LED connected in series to the green sub pixel GSP and the blue sub pixel BSP, and the first repair electrode REPE1 and the second repair electrode REPE2 may be disposed. This may be designed in various ways in consideration of power consumption efficiency of the display device 100 or an arrangement of the sub pixels SP.

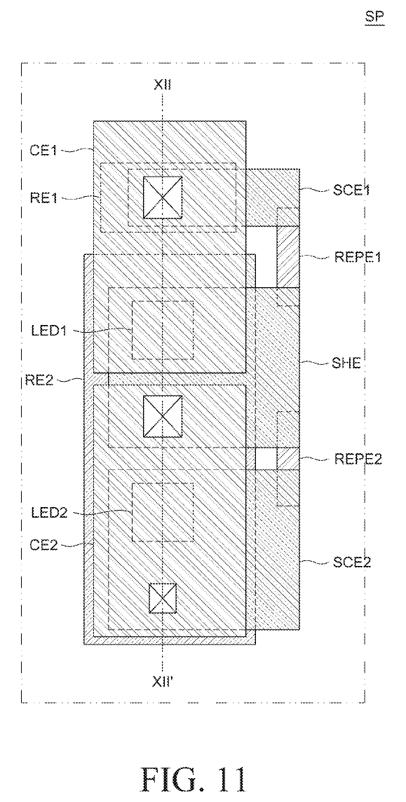

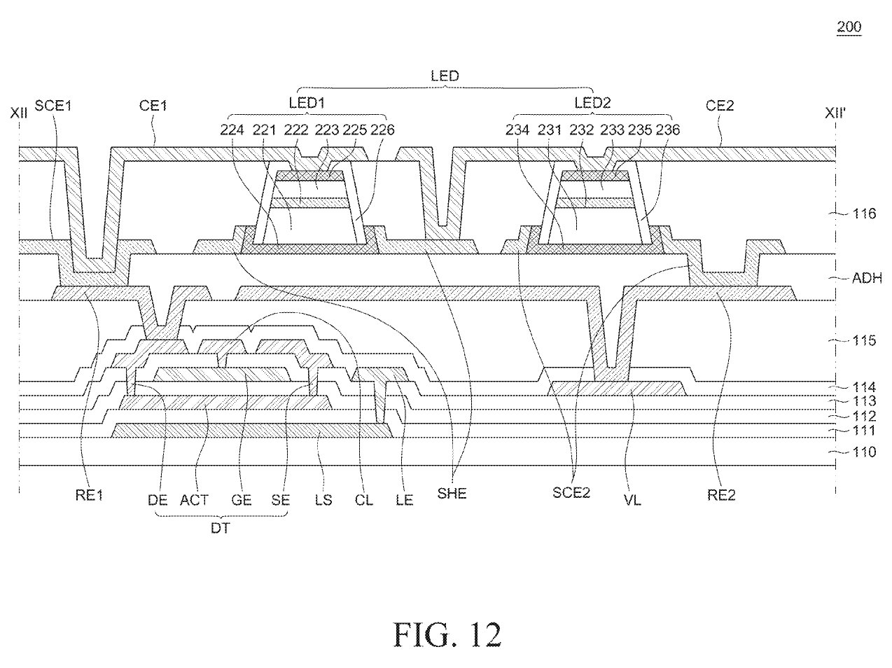

FIG. 11 is a plan view of a sub pixel of a display device according to one or more other embodiments of the present disclosure. FIG. 12 is a cross-sectional view taken along the line XII-XII' of FIG. 11. The only difference between a display device 200 of FIGS. 11 and 12 and the display device 100 of FIGS. 1 to 10C is a first reflective electrode RE1, a second reflective electrode RE2, an adhesive layer ADH, a light emitting element LED, a first sub connection electrode SCE1, a second sub connection electrode SCE2, a shared electrode SHE, a first connection electrode CE1, and a second connection electrode CE2, but other components are substantially the same, so that a redundant description will be omitted.

Referring to FIGS. 11 and 12, the first reflective electrode RE1 and the second reflective electrode RE2 which are spaced apart from each other may be disposed on the first planarization layer 115. The first reflective electrode RE1 and the second reflective electrode RE2 electrically connect the light emitting element LED to the power line VL and the driving transistor DT, and simultaneously, may serve as a reflective plate that reflects light emitted from the light emitting element LED to the upper portion of the light emitting element LED.

The first reflective electrode RE1 may electrically connect the driving transistor DT and the first light emitting element LED1. The first reflective electrode RE1 may be connected to the drain electrode DE of the driving transistor DT through a contact hole formed in the passivation layer 114 and the first planarization layer 115. Further, the first reflective electrode RE1 may be electrically connected to the second electrode 225 of the first light emitting element LED1 through the first connection electrode CE1.

The second reflective electrode RE2 may electrically connect the power line VL and the second light emitting element LED2. The second reflective electrode RE2 may be connected to the power line VL through a contact hole formed in the passivation layer 114 and the first planarization layer 115, and may be electrically connected to the first electrode 234 of the second light emitting element LED2 through a second sub connection electrode SCE2 to be described below.

The first repair electrode REPE1 and the second repair electrode REPE2 made of the same material as the first reflective electrode RE1 and the second reflective electrode RE2 may be disposed on the same layer as the first reflective electrode RE1 and the second reflective electrode RE2. That is, the first repair electrode REPE1 and the second repair electrode REPE2 may be disposed on the first planarization layer 115 like the first reflective electrode RE1 and the second reflective electrode RE2.

The first repair electrode REPE1 and the second repair electrode REPE2 are connected to the shared electrode SHE connecting the first light emitting element LED1 and the second light emitting element LED2 to form a path through which the current of the driving transistor DT or the power line VL detours. Therefore, even if any one of the first light emitting element LED1 and the second light emitting element LED2 connected in series is defective, the remaining one may be normally driven.

The first repair electrode REPE1 may be disposed between the first sub connection electrode SCE1 and the shared electrode SHE. In this case, at least a part of the first repair electrode REPE1 may be disposed to overlap the first sub connection electrode SCE1 and the shared electrode SHE. Therefore, when the first light emitting element LED1 is defective, a welding process may be performed by irradiating an overlapping point of the first sub connection electrode SCE1 and the first repair electrode REPE1 and an overlapping point of the shared electrode SHE and the first repair electrode REPE1 with a laser, such that the first repair electrode REPE1 to contact the first sub connection electrode SCE1 and the shared electrode SHE. Accordingly, the first sub connection electrode SCE1 and the shared electrode SHE may be connected through the first repair electrode REPE1. Therefore, the second light emitting element LED2 may be connected to the driving transistor DT through the shared electrode SHE, the first repair electrode REPE1, and the first sub connection electrode SCE1. Therefore, even though the first light emitting element LED1 which is connected to the second light emitting element LED2 in series is defective, the second light emitting element LED2 may be normally turned on by receiving the driving current of the driving transistor DT.

Meanwhile, the shared electrode SHE connected to the first electrode 224 of the first light emitting element LED1 and the first sub connection electrode SCE1 connected to the second electrode 225 of the first light emitting element LED1 are connected to each other through a welding process. Therefore, the same voltage is applied to the first electrode 224 and the second electrode 225 of the first light emitting element LED1 to completely darken the first light emitting element LED1.

On the contrary, when the first light emitting element LED1 is normal, the first repair electrode REPE1 may be in a floating state that is not connected to any other electrode including the first sub connection electrode SCE1 and the shared electrode SHE.

The second repair electrode REPE2 may be disposed between the shared electrode SHE and the second sub connection electrode SCEC2. In this case, at least a part of the second repair electrode REPE2 may be disposed to overlap the shared electrode SHE and the second sub connection electrode SCEC2. Therefore, when the second light emitting element LED2 is defective, a welding process may be performed by irradiating an overlapping point of the shared electrode SHE and the second repair electrode REPE2 and an overlapping point of the second sub connection electrode SCEC2 and the second repair electrode REPE2 with laser beams, such that the second repair electrode REPE2 is in contact with the second sub connection electrode SCEC2 and the shared electrode SHE. Accordingly, the second sub connection electrode SCEC2 and the shared electrode SHE may be connected through the second repair electrode REPE2. Therefore, the first light emitting element LED1 may be connected to the power line VL through the shared electrode SHE, the second repair electrode REPE2, and the second sub connection electrode SCEC2. Therefore, even though the second light emitting element LED2 which is connected to the first light emitting element LED1 in series is defective, the first light emitting element LED1 may be normally turned on by receiving the power current of the power line VL.

Meanwhile, the second reflective electrode RE2 connected to the first electrode 234 of the second light emitting element LED2 and the shared electrode SHE connected to the second electrode 235 of the second light emitting element LED2 are connected to each other through a welding process. Therefore, the same voltage is applied to the first electrode 234 and the second electrode 235 of the second light emitting element LED2 so that the second light emitting element LED2 may be completely darkened.

On the contrary, when the second light emitting element LED2 is normal, the second repair electrode REPE2 may be in a floating state that is not connected to any other electrode including the second sub connection electrode SCE2 and the shared electrode SHE.

Meanwhile, in order to prevent the driving transistor DT, the first reflective electrode RE1, and the second reflective electrode RE2 from being welding during the welding process of the first repair electrode REPE1 and the second repair electrode REPE2, the first repair electrode REPE1 and the second repair electrode REPE2 may be disposed so as not to overlap the driving transistor DT, the first reflective electrode RE1, and the second reflective electrode RE2, but are not limited thereto.

The adhesive layer ADH is formed on the front surface of the substrate 110 on the first reflective electrode RE1 and the second reflective electrode RE2 to fix the light emitting element LED disposed on the adhesive layer ADH. The adhesive layer ADH may be formed of a photocurable adhesive material that may be cured by light. For example, the adhesive layer ADH may be formed of an acrylic material including a photosensitizer, but is not limited thereto.

The plurality of light emitting elements LED may be disposed on the adhesive layer ADH. The plurality of light emitting elements LED may include a first light emitting element LED1 and a second light emitting element LED2 which are connected in series. The first light emitting element LED1 and the second light emitting element LED2 may emit light of the same color.

The first light emitting element LED1 may include a first semiconductor layer 221, an emission layer 222, a second semiconductor layer 223, a first electrode 224, a second electrode 225, and a passivation film 226.

First, the second semiconductor layer 223 may be disposed on the first semiconductor layer 221. Any one of the first semiconductor layer 221 and the second semiconductor layer 223 may be a semiconductor layer doped with an n-type impurity and the rest may be a semiconductor layer doped with a p-type impurity. For example, the first semiconductor layer 221 and the second semiconductor layer 223 may be layers doped with n-type and p-type impurities into a material such as gallium nitride (GaN), indium aluminum phosphide (InAlP), or gallium arsenide (GaAs).

The emission layer 222 may be disposed between the first semiconductor layer 221 and the second semiconductor layer 223. The emission layer 222 may emit light by receiving holes and electrons from the first semiconductor layer 221 and the second semiconductor layer 223.

The first electrode 224 may be disposed under the first semiconductor layer 221. The first electrode 224 is an electrode for electrically connecting the second electrode 225 of the second light emitting element LED2 and the first semiconductor layer 221 through the shared electrode SHE and the second connection electrode CE2. In this case, the first semiconductor layer 221 may be a semiconductor layer doped with an n-type impurity, and the first electrode 224 may be a cathode.

Meanwhile, the first electrode 224 may have a width greater than a width of the emission layer 222, the second semiconductor layer 223, the second electrode 225, particularly, the first semiconductor layer 221. When the first electrode 224 is formed, the width of the first electrode 224 may be formed to be larger than the sizes of the first semiconductor layer 221 and the passivation film 226. In this way, the first electrode 224 protrudes from the first semiconductor layer 221 to be disposed at the outermost side of the first light emitting element LED1, so that the first electrode 224 may be easily connected to the electrode of the display device 200.

Meanwhile, FIG. 12 illustrates that the first electrode 224 protrudes from the passivation film 226 to surround the side surface of the passivation film 226, but the present disclosure is not limited thereto, and the end of the first electrode 224 may be disposed on the same plane as the end of the passivation film 226.

The second electrode 225 may be disposed on the second semiconductor layer 223. The second electrode 225 is an electrode for electrically connecting the driving transistor DT and the second semiconductor layer 223. In this case, the second semiconductor layer 223 may be a semiconductor layer doped with a p-type impurity, and the second electrode 225 may be an anode.

A passivation film 226 surrounding the first semiconductor layer 221, the emission layer 222, the second semiconductor layer 223, and the second electrode 225 may be disposed. The passivation film 226 may be formed of an insulating material to protect the first semiconductor layer 221, the emission layer 222, and the second semiconductor layer 223.

Like the first light emitting element LED1, the second light emitting element LED2 may include a first semiconductor layer 231, an emission layer 232, a second semiconductor layer 233, a first electrode 234, a second electrode 235, and a passivation film 236. The shape of the second light emitting element LED2 and the arrangement structure of each component may be substantially the same as the shape of the first light emitting element LED1 and the arrangement structure of each component, and accordingly, a redundant description will be omitted.

The first sub connection electrode SCE1 and the second sub connection electrode SCE2 which are spaced apart from each other may be disposed on the adhesive layer ADH. The first sub connection electrode SCE1 is an electrode for electrically connecting the first light emitting element LED1 and the driving transistor DT. The first sub connection electrode SCE1 may be connected to the first reflective electrode RE1 through a contact hole formed in the adhesive layer ADH. Accordingly, the first sub connection electrode SCE1 may be connected to the driving transistor DT through the first reflective electrode RE1. For example, the first sub connection electrode SCE1 may connect the second electrode 225 of the first light emitting element LED1 and the drain electrode DE of the driving transistor DT, but is not limited thereto.

The second sub connection electrode SCE2 is an electrode for electrically connecting the second light emitting element LED2 and the power line VL. The second sub connection electrode SCE2 may be disposed to surround the lower edge of the second light emitting element LED2 and disposed on the side surface of the second light emitting element LED2. Therefore, the second sub connection electrode SCE2 may be connected to the first electrode 234 by contacting the first electrode 234. The second sub connection electrode SCE2 may be connected to the second reflective electrode RE2 through a contact hole formed in the adhesive layer ADH. Accordingly, the second sub connection electrode SCE2 may be electrically connected to the power line VL through the second reflective electrode RE2. For example, the second sub connection electrode SCE2 may connect the first electrode 234 of the second light emitting element LED2 and the power line VL, but is not limited thereto.

The shared electrode SHE may be disposed on the adhesive layer ADH to be spaced apart from the first sub connection electrode SCE1 and the second sub connection electrode SCE2. For example, the shared electrode SHE may be disposed between the first sub connection electrode SCE1 and the second sub connection electrode SCE2. The shared electrode SHE may electrically connect the first light emitting element LED1 and the second light emitting element LED2. For example, the shared electrode SHE may be disposed to surround the lower edge of the first light emitting element LED1 and disposed on the side surface of the first light emitting element LED1. Therefore, the shared electrode SHE may be connected to the first light emitting element LED1 by contacting the first electrode 224. Further, the shared electrode SHE may be connected to the second electrode 235 of the second light emitting element LED2 through a second connection electrode CE2 to be described below.

For example, the shared electrode SHE may be disposed on the same layer and made of the same material as the first sub connection electrode SCE1 and the second sub connection electrode SCE2, but is not limited thereto.

The first connection electrode CE1 and the second connection electrode CE2 may be disposed to be spaced apart from each other on the second planarization layer 116. The first connection electrode CE1 is an electrode for electrically connecting the first light emitting element LED1 and the driving transistor DT. The first connection electrode CE1 may be connected to the first sub connection electrode SCE1 through a contact hole formed in the second planarization layer 116. Accordingly, the first connection electrode CE1 may be connected to the driving transistor DT through the first sub connection electrode SCE1 and the first reflective electrode RE1. For example, the first connection electrode CE1 may connect the second electrode 225 of the first light emitting element LED1 and the drain electrode DE of the driving transistor DT, but is not limited thereto.

The second connection electrode CE2 is an electrode for electrically connecting the second light emitting element LED2 to the shared electrode SHE. The second connection electrode CE2 may be connected to the shared electrode SHE through a contact hole formed in the second planarization layer 116. Accordingly, the second connection electrode CE2 may connect the second electrode 235 of the second light emitting element LED2 to the shared electrode SHE, but is not limited thereto.

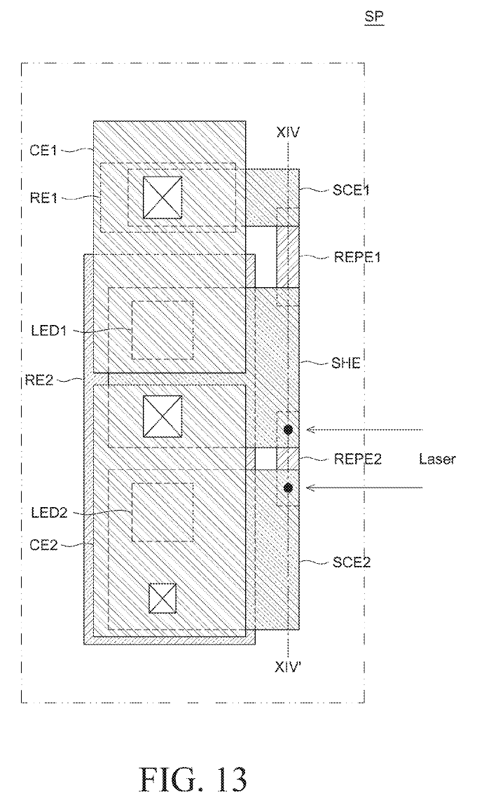

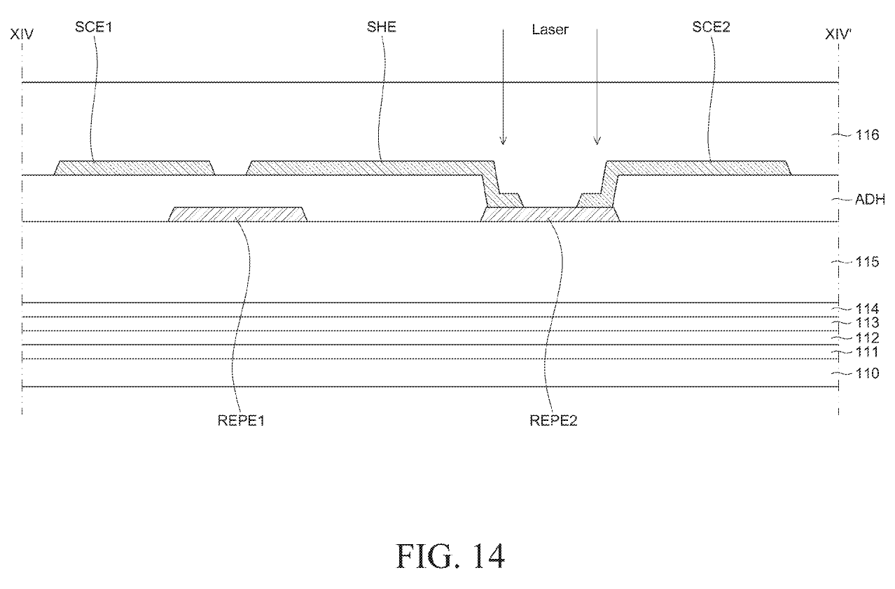

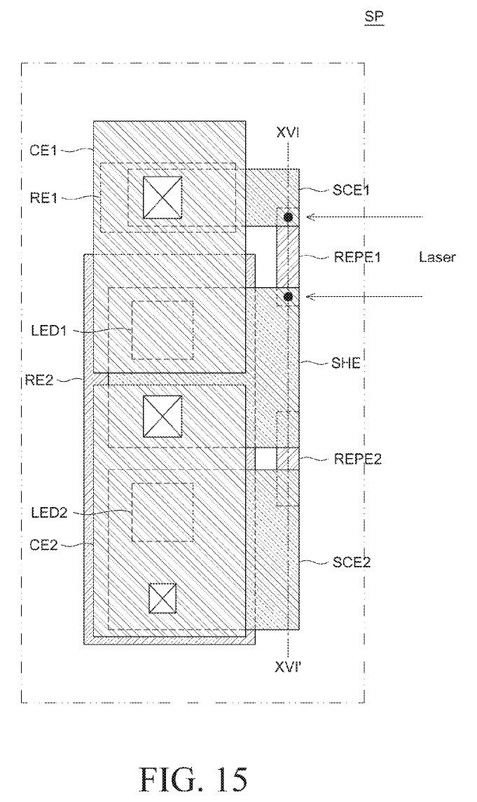

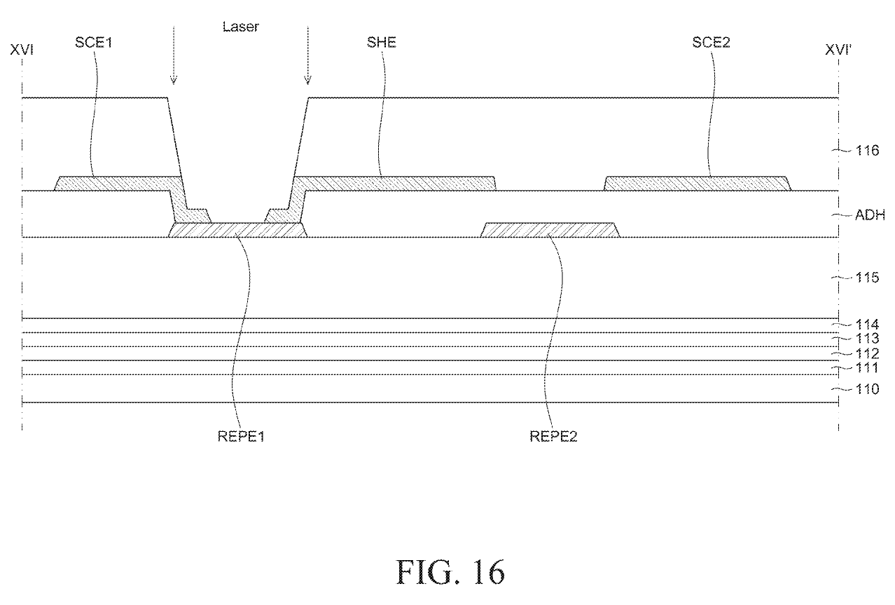

FIG. 13 is a plan view of a sub pixel of a display device according to one or more other embodiments of the present disclosure. FIG. 14 is a cross-sectional view taken along the line XIV-XIV’ of FIG. 13. FIG. 15 is a plan view of a sub pixel of a display device according to one or more other embodiments of the present disclosure. FIG. 16 is a cross-sectional view taken along the line XVI-XVI' of FIG. 14. Specifically, FIGS. 13 and 14 are views for explaining a repair method when the second light emitting element LED2 is defective among the plurality of light emitting elements LED, and FIGS. 15 and 16 are views for explaining a repair method when the first light emitting element LED1 is defective among the plurality of light emitting elements LED.

In the display device 200 according to one or more other embodiments of the present disclosure, when any one of the plurality of light emitting elements LED is defective, the shared electrode SHE connecting the plurality of light emitting elements LED and the first sub connection electrode SCE1 or the second sub connection electrode SCE2 are normally driven by performing a welding process to minimize or reduce the defect in which the corresponding sub pixel SP is completely darkened.

Meanwhile, since the possibility that both the first light emitting element LED1 and the second light emitting element LED2 are defective is remarkably low, it will be assumed and described hereinafter that if one of the light emitting elements LED is found to be defective, the other is normal, and thus a lighting test for the other is unnecessary.

First, referring to FIGS. 13 and 14, a lighting test of the second light emitting element LED2 may be performed before the process of forming the second planarization layer 116. Since the first electrode 234 of the second light emitting element LED2 is connected to the power line VL through the second sub connection electrode SCE2, a lighting test may be performed by applying a lighting test signal to the second electrode 235 through the power line VL and to the second electrode 235 through a probe. When the second light emitting element LED2 is defective as a result of the lighting test, the welding process may be performed by irradiating the overlapping point of the shared electrode SHE and the second repair electrode REPE2 and the overlapping point of the second sub connection electrode SCE2 and the second repair electrode REPE2 with laser beams, such that the second repair electrode REPE2 may be in contact with the second sub connection electrode SCE2 and the shared electrode SHE.

Specifically, referring to FIG. 14, when the welding process is performed by irradiating the shared electrode SHE and the second sub connection electrode SCE2 with laser beams, the adhesive layer ADH between the shared electrode SHE and the second sub connection electrode SCE2 and the second repair electrode REPE2 may be opened, and the shared electrode SHE and a part of the second sub connection electrode SCE2 may be melted and the shared electrode SHE and the second sub connection electrode SCE2 may be connected to the second repair electrode REPE2.

Accordingly, the second sub connection electrode SCE2 and the shared electrode SHE may be connected through the second repair electrode REPE2. Therefore, the second sub connection electrode SCE2 connected to the first electrode 234 of the second light emitting element LED2 and the shared electrode SHE connected to the second electrode 235 of the second light emitting element LED2 are connected to each other, such that the same voltage is applied to the first electrode 234 and the second electrode 235 of the second light emitting element LED2. Therefore, the second light emitting element LED2 may be completely darkened.

Thereafter, the second planarization layer 116, the first connection electrode CE1, and the second connection electrode CE2 are formed to turn on only the first light emitting element LED1. For example, when both the first light emitting element LED1 and the second light emitting element LED2 are normal, the first light emitting element LED1 is connected to the power line VL through the second light emitting element LED2. However, because the shared electrode SHE is connected to the second sub connection electrode SCE2 through the second repair electrode REPE2, the first light emitting element LED1 may be connected to the power line VL through the shared electrode SHE, the second repair electrode REPE2, and the second sub connection electrode SCE2.

That is, a current path between the first light emitting element LED1 and the power line VL may be formed through the shared electrode SHE and the second repair electrode REPE2. Therefore, even though the second light emitting element LED2 which is connected to the first light emitting element LED1 in series is defective, the power current detours to the first light emitting element LED1 and the first light emitting element LED1 may be normally driven.

In this case, since the first light emitting element LED1 is normal, the first repair electrode REPE1 may be in a floating state that is not connected to any other electrode including the first sub connection electrode SCE1 and the shared electrode SHE.

Referring to FIGS. 15 and 16, as described above, there are remarkably few cases where both the first light emitting element LED1 and the second light emitting element LED2 are defective so that the lighting test of the first light emitting element LED1 may be performed only when the second light emitting element LED2 is normal as a result of the lighting test of the second light emitting element LED2.

Unlike the lighting test of the second light emitting element LED2, the lighting test of the first light emitting element LED1 may be performed after the lighting test of the second light emitting element LED2 and after the second planarization layer 116, the first connection electrode CE1, and the second connection electrode CE2 are all formed.

As a result of the lighting test of the first light emitting element LED1, a welding process may be performed by irradiating an overlapping point between the first sub connection electrode SCE1 and the first repair electrode REPE1 and an overlapping point between the shared electrode SHE and the first repair electrode REPE1 by irradiating a laser to cause the first repair electrode REPE1 to contact the first sub connection electrode SCE1 and the shared electrode SHE.

Specifically, referring to FIG. 16, when the welding process is performed by irradiating the shared electrode SHE and the first sub connection electrode SCE1 with laser beams, the second planarization layer 116 disposed on the shared electrode SHE and the first sub connection electrode SCE1 and the adhesive layer ADH between the shared electrode SHE and the first sub connection electrode SCE1 and the first repair electrode REPE1 may be opened, a part of the shared electrode SHE and the first sub connection electrode SCE1 may be melted, and the shared electrode SHE and the first sub connection electrode SCE1 may be connected to the first repair electrode REPE1. FIG. 16 illustrates that the second planarization layer 116 is opened by laser irradiation, but is not limited thereto. The second planarization layer 116 is not opened and maintains the same shape as FIG. 14. The adhesive layer ADH between the shared electrode SHE and the first sub connection electrode SCE1 is opened so that the shared electrode SHE and the first sub connection electrode SCE1 may be connected to the first repair electrode REPE1.

Accordingly, the first sub connection electrode SCE1 and the shared electrode SHE may be connected through the first repair electrode REPE1. Therefore, the shared electrode SHE connected to the first electrode 224 of the first light emitting element LED1 and the first sub connection electrode SCE1 connected to the second electrode 225 of the first light emitting element LED1 are connected to each other, such that the same voltage is applied to the first electrode 224 and the second electrode 225 of the first light emitting element LED1, so the first light emitting element LED1 may be completely darkened.

Therefore, only the second light emitting element LED2 may be turned on. For example, when both the first light emitting element LED1 and the second light emitting element LED2 are normal, the second light emitting element LED2 is connected to the driving transistor DT through the first light emitting element LED1. However, since the shared electrode SHE is connected to the first sub connection electrode SCE1 through the first repair electrode REPE1, the second light emitting element LED2 may be connected to the driving transistor DT through the shared electrode SHE, the first repair electrode REPE1, and the first sub connection electrode SCE1.

That is, a current path between the second light emitting element LED2 and the driving transistor DT may be formed through the shared electrode SHE and the first repair electrode REPE1. Therefore, even though the first light emitting element LED1 which is connected to the second light emitting element LED2 in series is defective, the driving current detours to the second light emitting element LED2 and the second light emitting element LED2 may be normally driven.

In this case, since the second light emitting element LED2 is normal, the second repair electrode REPE2 may be in a floating state that is not connected to any other electrode including the second sub connection electrode SCE2 and the shared electrode SHE.

In the display device 200 according to one or more other embodiments of the present disclosure, the first light emitting element LED1 and the second light emitting element LED2 which are connected to each other in series may be disposed in one sub pixel SP. For example, the first light emitting element LED1 and the second light emitting element LED2 may be connected through the shared electrode SHE. Specifically, the second electrode 225 of the first light emitting element LED1 may be connected to the driving transistor DT, the first electrode 234 of the second light emitting element LED2 may be connected to the power line VL, and the shared electrode SHE may be connected to the first electrode 224 of the first light emitting element LED1 and the second electrode 235 of the second light emitting element LED2. Therefore, the first light emitting element LED1 may be connected to the power line VL through the second light emitting element LED2, and the second light emitting element LED2 may be connected to the driving transistor DT through the first light emitting element LED1. As described above, the first light emitting element LED1 and the second light emitting element LED2 are connected in series to reduce the current flowing through each sub pixel SP, thereby reducing power consumption.

Specifically, in the display device 200 according to one or more other embodiments of the present disclosure, the shared electrode SHE connecting the first light emitting element LED1 and the second light emitting element LED2 is connected to the first repair electrode REPE1 or the second repair electrode REPE2 to form a path through which the current of the driving transistor DT or the power line VL detours. Therefore, even though any one of the first light emitting element LED1 and the second light emitting element LED2 connected in series is defective, the remaining one may be normally driven. For example, in the display device 200 according to one or more other embodiments of the present disclosure, when the first light emitting element LED1 is defective, a welding process may be performed to connect the first sub connection electrode SCE1 and the shared electrode SHE1 to each other through the first repair electrode REPE1 by irradiating an overlapping point of the first sub connection electrode SCE1 and the first repair electrode REPE1 with a laser at overlapping point of the shared electrode SHE and the first repair electrode REPE1. Therefore, the second light emitting element LED2 may be connected to the driving transistor DT through the shared electrode SHE, the first repair electrode REPE1, and the first sub connection electrode SCE1. That is, a current path between the second light emitting element LED2 and the driving transistor DT may be formed through the shared electrode SHE and the first repair electrode REPE1. Therefore, the driving current detours to the second light emitting element LED2, and even though the first light emitting element LED1 is defective, the second light emitting element LED2 may be normally driven. Accordingly, it is possible to minimize or reduce a defect in which the sub pixels SP are completely darkened. In addition, since the shared electrode SHE connected to the first electrode 224 of the first light emitting element LED1 and the first sub connection electrode SCE1 connected to the second electrode 225 of the first light emitting element LED1 are connected to each other, the same voltage is applied to the first electrode 224 and the second electrode 225 of the first light emitting element LED1, so that the first light emitting element LED1 may be completely darkened.

Likewise, in the display device 200 according to one or more other embodiments of the present disclosure, when the second light emitting element LED2 is defective, a welding process may be performed to connect the second sub connection electrode SCE2 and the shared electrode SHE to each other through the second repair electrode REPE2 by irradiating a laser to the overlapping point of the second sub connection electrode SCE2 and the second repair electrode REPE2 and overlapping the shared electrode SHE2. Therefore, the first light emitting element LED1 may be connected to the power line VL through the shared electrode SHE, the second repair electrode REPE2, and the second sub connection electrode SCE2. That is, a current path between the first light emitting element LED1 and the power line VL may be formed through the shared electrode SHE and the second repair electrode REPE2. Therefore, the power current detours to the first light emitting element LED1, and even though the second light emitting element LED2 is defective, the first light emitting element LED1 may be normally driven. Accordingly, it is possible to minimize or reduce a defect in which the sub pixels SP are completely darkened. Further, the second sub connection electrode SCE2 connected to the first electrode 234 of the second light emitting element LED2 and the shared electrode SHE connected to the second electrode 235 of the second light emitting element LED2 are connected to each other. Therefore, the same voltage is applied to the first electrode 234 and the second electrode 235 of the second light emitting element LED2 so that the second light emitting element LED2 may be completely darkened.

In the display device 200 according to one or more other embodiments of the present disclosure, the series connection structure of the light emitting element LED and the repair structure through the first repair electrode REPE1 and the second repair electrode REPE2 may be selectively applied in consideration of power consumption efficiency of each sub pixel SP. For example, a plurality of light emitting elements LED which is connected in series only to the red sub pixel RSP having a lower power consumption efficiency than the green sub pixel GSP and the blue sub pixel BSP may be disposed, and only one light emitting element LED may be disposed in each of the green sub pixel GSP and the blue sub pixel BSP. Therefore, the repair structure using the first repair electrode REPE1 and the second repair electrode REPE2 may also be applied only to the red sub pixel RSP. However, the present disclosure is not limited thereto. The plurality of light emitting elements LED connected in series to the green sub pixel GSP and the blue sub pixel BSP and the first repair electrode REPE1 and the second repair electrode REPE2 may be disposed. The plurality of light emitting elements LED and the first repair electrode REPE1 and the second repair electrode REPE2 may be designed in various ways in consideration of power consumption efficiency of the display device 200 or a placement structure of the sub pixel SP.

The embodiments of the present disclosure can also be described as follows:

A display device according to one or more embodiments of the present disclosure may include a substrate in which a plurality of sub pixels is defined, a driving transistor and a power line disposed to be spaced apart from each other on the substrate, a plurality of light emitting elements including a first light emitting element disposed in at least some of the plurality of sub pixels and a second light emitting element connected in series with the first light emitting element, and a shared electrode disposed on the substrate and electrically connecting the first light emitting element and the second light emitting element in at least some of the plurality of sub pixels, the first light emitting element and the second light emitting element each include a first electrode and a second electrode, the second electrode of the first light emitting element is electrically connected to the driving transistor, the first electrode of the second light emitting element is electrically connected to the power line, and the shared electrode is electrically connected to the first light emitting element and the second electrode of the second light emitting element.

According to one or more embodiments of the present disclosure, the display device may further include a first reflective electrode and a second reflective electrode disposed to be spaced apart from each other on the driving transistor and the power line, the first reflective electrode may electrically connect the driving transistor and the second electrode of the first light emitting element, the second reflective electrode may electrically connect the power line and the first electrode of the second light emitting element, and the shared electrode may be disposed between the first reflective electrode and the second reflective electrode on the same layer as the first reflective electrode and the second reflective electrode, and may be formed of the same material as the first reflective electrode and the second reflective electrode.

According to one or more embodiments of the present disclosure, the display device may further comprise a bonding layer disposed on each of the shared electrode and the second reflective electrode and made of a conductive material, the first light emitting element may be disposed on the bonding layer on the shared electrode, and the second light emitting element may be disposed on the bonding layer on the second reflective electrode.

According to one or more embodiments of the present disclosure, the display device may further include a first repair electrode which is disposed between the first reflective electrode and the shared electrode so as to at least partially overlap the first reflective electrode and the shared electrode, and which does not overlap the driving transistor, and a second repair electrode which is disposed between the shared electrode and the second reflective electrode so as to at least partially overlap the shared electrode and the second reflective electrode, and does not overlap the driving transistor.

According to one or more embodiments of the present disclosure, the first repair electrode and the second repair electrode may be floated.

According to one or more embodiments of the present disclosure, the second light emitting element among the plurality of light emitting elements is a defective light emitting element, the first repair electrode may be floated, and the second repair electrode may be in contact with the shared electrode and the second reflective electrode.

According to one or more embodiments of the present disclosure, the first light emitting element among the plurality of light emitting elements is a defective light emitting element, the first repair electrode is in contact with the first reflective electrode and the shared electrode, and the second repair electrode may be floated.

According to one or more embodiments of the present disclosure, the first repair electrode and the second repair electrode may be disposed on the same layer as the source electrode and the drain electrode of the driving transistor and may be formed of the same material.

According to one or more embodiments of the present disclosure, the display device may further include a first connection electrode electrically connecting the second electrode of the first light emitting element and the first reflective electrode, and a second connection electrode electrically connecting the second electrode of the second light emitting element and the shared electrode.

According to one or more embodiments of the present disclosure, the display device may further include a first reflective electrode and a second reflective electrode disposed to be spaced apart from each other on the driving transistor and the power line, the first reflective electrode may electrically connect the driving transistor and the second electrode of the first light emitting element, and the second reflective electrode may electrically connect the power line and the first electrode of the second light emitting element.

According to one or more embodiments of the present disclosure, the display device may further include a first sub connection electrode and a second sub connection electrode disposed on the first reflective electrode and the second reflective electrode to be spaced apart from each other, the first sub connection electrode may electrically connect the driving transistor and the second electrode of the first light emitting element, the second sub connection electrode may electrically connect the power line and the first electrode of the second light emitting element, the shared electrode may be disposed on the same layer as the first sub connection electrode and the second sub connection electrode, made of the same material, and the shared electrode may be disposed between the first sub connection electrode and the second sub connection electrode.

According to one or more embodiments of the present disclosure, the display device may further include a first repair electrode which is disposed between the first sub connection electrode and the shared electrode so as to at least partially overlap the first sub connection electrode and the shared electrode and does not overlap the first reflective electrode and the second reflective electrode, and a second repair electrode which is disposed between the shared electrode and the second sub connection electrode so as to at least partially overlap the shared electrode and the second sub connection electrode and does not overlap the driving transistor, the first reflective electrode, and the second reflective electrode.

According to one or more embodiments of the present disclosure, the first repair electrode and the second repair electrode may be floated.

According to one or more embodiments of the present disclosure, the second light emitting element among the plurality of light emitting elements is a defective light emitting element, the first repair electrode may be floated, and the second repair electrode may be in contact with the shared electrode and the second sub connection electrode.

According to one or more embodiments of the present disclosure, the first light emitting element among the plurality of light emitting elements may be a defective light emitting element, the first repair electrode may be in contact with the first sub connection electrode and the shared electrode, and the second repair electrode may be floated.

According to one or more embodiments of the present disclosure, the first repair electrode and the second repair electrode may be disposed on the same layer as the first reflective electrode and the second reflective electrode and may be formed of the same material.

According to one or more embodiments of the present disclosure, each of the first light emitting element and the second light emitting element may further include a first semiconductor layer, an emission layer, and a second semiconductor layer which are sequentially disposed between the first electrode and the second electrode, a width of the first electrode may be larger than a width of each of the first semiconductor layer, the emission layer, the second semiconductor layer, and the second electrode, the shared electrode may be disposed on a side surface of the first light emitting element to be electrically connected to the first electrode of the first light emitting element, and the second sub connection electrode may be disposed on a side surface of the second light emitting element to be electrically connected to the first electrode of the second light emitting element.

According to one or more embodiments of the present disclosure, the display device may further include a first connection electrode which electrically connects the first sub connection electrode and the second electrode of the first light emitting element, and a second connection electrode which electrically connects the shared electrode and the second electrode of the second light emitting element.

According to one or more embodiments of the present disclosure, the plurality of sub pixels may include a red sub pixel, a green sub pixel, and a blue sub pixel, and the shared electrode may be disposed in the red sub pixel among the plurality of sub pixels.

According to one or more embodiments of the present disclosure, the shared electrode may be further disposed in the green sub pixel among the plurality of sub pixels.

Although the embodiments of the present disclosure have been described in detail with reference to the accompanying drawings, the present disclosure is not limited thereto and may be embodied in various forms without departing from the technical concept of the present disclosure.

Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all embodiments and do not limit the present disclosure.

What is claimed is:

1. A display device, comprising:
a substrate on which a plurality of sub pixels are defined;
a driving transistor and a power line disposed on the substrate to be spaced apart from each other;
a plurality of light emitting elements including a first light emitting element and a second light emitting element, the first light emitting element disposed in at least some of the plurality of sub pixels, and the second light emitting element connected in series with the first light emitting element; and
a shared electrode disposed on the substrate, the shared electrode electrically connecting the first light emitting element and the second light emitting element in at least some of the plurality of sub pixels,
wherein each of the first light emitting element and the second light emitting element includes a first electrode and a second electrode,
wherein the second electrode of the first light emitting element is electrically connected to the driving transistor,
wherein the first electrode of the second light emitting element is electrically connected to the power line, and
wherein the shared electrode is electrically connected to the first light emitting element and the second electrode of the second light emitting element.

2. The display device of claim 1, further comprising:
a first reflective electrode and a second reflective electrode which are disposed to be spaced apart from each other on the driving transistor and the power line,
wherein the first reflective electrode electrically connects the driving transistor and the second electrode of the first light emitting element,
wherein the second reflective electrode electrically connects the power line and the first electrode of the second light emitting element,
wherein the shared electrode is disposed between the first reflective electrode and the second reflective electrode on a same layer as the first reflective electrode and the second reflective electrode, and
wherein the shared electrode is formed of a same material as the first reflective electrode and the second reflective electrode.

3. The display device of claim 2, further comprising:
a bonding layer respectively disposed on the shared electrode and the second reflective electrode and made of a conductive material,
wherein the first light emitting element is disposed on the bonding layer on the shared electrode, and
wherein the second light emitting element is disposed on the bonding layer on the second reflective electrode.

4. The display device of claim 2, further comprising:
a first repair electrode which is disposed between the first reflective electrode and the shared electrode so as to at least partially overlap the first reflective electrode and the shared electrode and does not overlap the driving transistor; and
a second repair electrode which is disposed between the shared electrode and the second reflective electrode so as to at least partially overlap the shared electrode and the second reflective electrode and does not overlap the driving transistor.

5. The display device of claim 4, wherein the first repair electrode and the second repair electrode are floated.

6. The display device of claim 4, wherein the second light emitting element among the plurality of light emitting elements is a defective light emitting element,
wherein the first repair electrode is floated, and
wherein the second repair electrode is in contact with the shared electrode and the second reflective electrode.

7. The display device of claim 4, wherein the first light emitting element among the plurality of light emitting elements is a defective light emitting element,
wherein the first repair electrode is in contact with the first reflective electrode and the shared electrode, and
wherein the second repair electrode is floated.

8. The display device of claim 4, wherein the first repair electrode and the second repair electrode are disposed on a same layer as a source electrode and a drain electrode of the driving transistor, and wherein the first repair electrode and the second repair electrode are formed of a same material as the source electrode and the drain electrode of the driving transistor.

9. The display device of claim 2, further comprising:
a first connection electrode electrically connecting the second electrode of the first light emitting element and the first reflective electrode; and
a second connection electrode electrically connecting the second electrode of the second light emitting element and the shared electrode.

10. The display device of claim 1, further comprising:
a first reflective electrode and a second reflective electrode disposed to be spaced apart from each other on the driving transistor and the power line,
wherein the first reflective electrode electrically connects the driving transistor and the second electrode of the first light emitting element, and
wherein the second reflective electrode electrically connects the power line and the first electrode of the second light emitting element.

11. The display device of claim 10, further comprising:
a first sub connection electrode and a second sub connection electrode which are disposed to be spaced apart from each other on the first reflective electrode and the second reflective electrode,
wherein the first sub connection electrode electrically connects the driving transistor and the second electrode of the first light emitting element,
wherein the second sub connection electrode electrically connects the power line and the first electrode of the second light emitting element,
wherein the shared electrode is disposed on a same layer as the first sub connection electrode and the second sub connection electrode,
wherein the shared electrode is made of a same material as the first sub connection electrode and the second sub connection electrode, and
wherein the shared electrode is disposed between the first sub connection electrode and the second sub connection electrode.

12. The display device of claim 11, further comprising:
a first repair electrode which is disposed between the first sub connection electrode and the shared electrode so as to at least partially overlap the first sub connection electrode and the shared electrode and does not overlap the driving transistor, the first reflective electrode and the second reflective electrode; and
a second repair electrode which is disposed between the shared electrode and the second sub connection electrode so as to at least partially overlap the shared electrode and the second sub connection electrode and does not overlap the driving transistor, the first reflective electrode and the second reflective electrode.

13. The display device of claim 12, wherein the first repair electrode and the second repair electrode are floated.

14. The display device of claim 12, wherein the second light emitting element among the plurality of light emitting elements is a defective light emitting element,
wherein the first repair electrode is floated, and
wherein the second repair electrode is in contact with the shared electrode and the second sub connection electrode.

15. The display device of claim 12, wherein the first light emitting element among the plurality of light emitting elements is a defective light emitting element,
wherein the first repair electrode is in contact with the first sub connection electrode and the shared electrode, and
wherein the second repair electrode is floated.

16. The display device of claim 12, wherein the first repair electrode and the second repair electrode are disposed on a same layer as the first reflective electrode and the second reflective electrode, and wherein the first repair electrode and the second repair electrode are formed of a same material as the first reflective electrode and the second reflective electrode.

17. The display device of claim 11, wherein each of the first light emitting element and the second light emitting element further includes a first semiconductor layer, an emission layer, and a second semiconductor layer sequentially disposed between the first electrode and the second electrode,
wherein a width of the first electrode is larger than a width of each of the first semiconductor layer, the emission layer, the second semiconductor layer, and the second electrode, and
wherein the shared electrode is disposed on a side surface of the first light emitting element to be electrically connected to the first electrode of the first light emitting element, and
wherein the second sub connection electrode is disposed on a side surface of the second light emitting element to be electrically connected to the first electrode of the second light emitting element.

18. The display device of claim 11, further comprising:
a first connection electrode electrically connecting the first sub connection electrode and the second electrode of the first light emitting element; and
a second connection electrode electrically connecting the shared electrode and the second electrode of the second light emitting element.

19. The display device of claim 1, wherein the plurality of sub pixels include a red sub pixel, a green sub pixel, and a blue sub pixel, and
wherein the shared electrode is disposed in the red sub pixel among the plurality of sub pixels.

20. The display device of claim 19, wherein the shared electrode is further disposed in the green sub pixel among the plurality of sub pixels.

21. A display device, comprising:
a substrate on which a plurality of sub pixels are defined;
a power line for supplying power to the plurality of sub pixels, the power line disposed on the substrate; and
a planarization layer disposed further from the substrate than the power line in a cross-sectional view of the display device,
wherein a first sub pixel of the plurality of sub pixels comprises:
a driving transistor between the planarization layer and the substrate in the cross-sectional view of the display device,
a shared electrode disposed on the planarization layer,
a first light emitting element disposed on the planarization layer, the first light emitting element including a first electrode connected to the shared electrode and a second electrode connected to the driving transistor, and
a second light emitting element disposed on the planarization layer, the second light emitting element including a first electrode connected to the power line and a second electrode connected to the shared electrode.

22. The display device of claim 21, wherein the first sub pixel further comprises:
a first reflective electrode for reflecting light emitted from the first light emitting element, the first reflective electrode disposed on the planarization layer and in a same layer as the shared electrode, the first reflective electrode connecting the second electrode of the first light emitting element with the driving transistor; and
a second reflective electrode for reflecting light emitted from the second light emitting element, the second reflective electrode disposed on the planarization layer and in the same layer as the shared electrode, the second reflective electrode connecting the first electrode of the second light emitting element with the power line.

23. The display device of claim 22, wherein the first sub pixel further comprises:
a first repair electrode disposed between the substrate and the planarization layer in the cross-sectional view of the display device, the first repair electrode overlapping a portion of the first reflective electrode and a first portion of the shared electrode in a plan view of the display device; and
a second repair electrode disposed between the substrate and the planarization layer in the cross-sectional view of the display device and in a same layer as the first repair electrode, the second repair electrode overlapping a second portion of the shared electrode and a portion of the second reflective electrode in the plan view of the display device.

24. The display device of claim 23, wherein when the second light emitting element is defective, an opening is formed in a cross-section of a portion of the planarization layer between the shared electrode and the second reflective electrode in the plan view of the display device,
wherein a portion of the second repair electrode overlaps the opening in the plan view of the display device, and
wherein the shared electrode is connected to the second reflective electrode through the opening and the second repair electrode.

25. The display device of claim 23, wherein when the first light emitting element is defective, an opening is formed in a cross-section of a portion of the planarization layer between the first reflective electrode and the shared electrode in the plan view of the display device,
wherein a portion of the first repair electrode overlaps the opening in the plan view of the display device, and
wherein the first reflective electrode is connected to the shared electrode through the opening and the first repair electrode.

26. The display device of claim 22, further comprising:
a second planarization layer disposed on the planarization layer,
wherein the first sub pixel further comprises:
a first connection electrode disposed on the second planarization layer and connecting the second electrode of the first light emitting element to the first reflective electrode via a first opening formed in the second planarization layer, and
a second connection electrode disposed on the second planarization layer and connecting the second electrode of the second light emitting element to the second reflective electrode via a second opening formed in the second planarization layer.
